(19) United States
(12) Patent Application Publication
(10) Pub. No.: US 2026/0311743 A1
(43) Pub. Date: Oct. 8, 2026

(54) PERIPHERAL CIRCUIT AND MEMORY DEVICE INCLUDING THE SAME

(71) Applicant: SAMSUNG ELECTRONICS CO., LTD., Suwon-si (KR)

(72) Inventors: Changyoung LEE, Suwon-si (KR); Young Seok PARK, Suwon-si (KR); Kyu-Chang KANG, Suwon-si (KR); Younghun SEO, Suwon-si (KR)

(73) Assignee: SAMSUNG ELECTRONICS CO., LTD., Suwon-si (KR)

(21) Appl. No.: 19/400,447

(22) Filed: Nov. 25, 2025

(30) Foreign Application Priority Data
Apr. 8, 2025 (KR) 10-2025-0045150

(51) Int. Cl. G11C 11/4091; G11C 11/4094; G11C 11/4096

(52) U.S. Cl. CPC G11C 11/4091; G11C 11/4094; G11C 11/4096

(57) ABSTRACT

A memory device includes a cell array having first and second sub cell arrays, and first and second bit line sense amplifiers connected, respectively, to the first and second sub cell arrays. The memory device also includes first and second local I/O line pairs electrically connected, respectively, to a first bit line pair connected to the first bit line sense amplifier and a second bit line pair connected to the second bit line sense amplifier. The memory device further includes a common local I/O line pair connected to the first and second local I/O line pairs, a common local sense amplifier configured to amplify a voltage level transferred from the common local I/O line pair, a global I/O line pair connected to the common local sense amplifier, and an I/O sense amplifier electrically connected to the global I/O line pair.

### CROSS-REFERENCE TO RELATED APPLICATION

This application claims priority to Korean Patent Application No. 10-2025-0045150, filed in the Korean Intellectual Property Office on Apr. 8, 2025, the entire contents of which are hereby incorporated by reference.

### BACKGROUND

### 1. Field

This disclosure relates to a peripheral circuit and a memory device including the peripheral circuit.

### 2. Description of Related Art

A dynamic random access memory (DRAM) may operate by writing and reading data according to charge stored in a cell capacitor of a memory cell. In DRAM, a memory cell array may be connected to bit lines and complementary bit lines. When a read operation is performed, a bit line sense amplifier may sense and amplify a voltage difference between the bit line and the complementary bit line, that is, between a bit line pair. Data of the bit line pair sensed by the bit line sense amplifier may be selectively transferred to a local input/output (I/O) line pair through column select transistors, and a local sense amplifier may amplify data of the local I/O line pair. Data of the local I/O line pair amplified by the local sense amplifier may be transferred to a global I/O line pair, and a global I/O line sense amplifier may amplify data of the global I/O line pair and output the amplified data to the outside through data pads as read data.

### SUMMARY

Embodiments of the present disclosure relate to a peripheral circuit and a memory device including the peripheral circuit that reduce data bottlenecks inside a memory device and improve data transfer speed.

The objectives to be achieved by the present disclosure are not limited to those described above, and other objectives not mentioned will be clearly understood by those of ordinary skill in the art from the following description.

In some embodiments, a memory device may include a cell array including a first sub cell array and a second sub cell array, a first bit line sense amplifier connected to the first sub cell array, a second bit line sense amplifier connected to the second sub cell array, a first local input/output (I/O) line pair electrically connected to a first bit line pair connected to the first bit line sense amplifier, a second local I/O line pair electrically connected to a second bit line pair connected to the second bit line sense amplifier, a common local I/O line pair connected to the first local I/O line pair and the second local I/O line pair, a common local sense amplifier configured to amplify a voltage level transferred from the common local I/O line pair, a global I/O line pair connected to the common local sense amplifier, and an I/O sense amplifier electrically connected to the global I/O line pair.

In some embodiments, a memory device, may include a cell array including a first sub cell array and a second sub cell array, a first bit line sense amplifier connected to the first sub cell array, a second bit line sense amplifier connected to the second sub cell array, a first local I/O line pair electrically connected to a first bit line pair connected to the first bit line sense amplifier, a second local I/O line pair electrically connected to a second bit line pair connected to the second bit line sense amplifier, a common local I/O line pair, connected to the first local I/O line pair and the

second local I/O line pair, the common local I/O line pair including a common local I/O line and a complementary common local I/O line, a plurality of transmission gate circuits configured to electrically connect the common local I/O line pair to one of the first local I/O line pair or the second local I/O line pair and to electrically isolate the common local I/O line pair from the other of the first local I/O line pair or the second local I/O line pair, a common local sense amplifier, disposed between a first set of bit line sense amplifiers that includes the first bit line sense amplifier and is connected to the first sub cell array and a second set of bit line sense amplifiers that includes the second bit line sense amplifier and is connected to the second sub cell array, and configured to amplify a voltage level transferred from the common local I/O line pair, a global I/O line pair connected to the common local sense amplifier, and an I/O sense amplifier electrically connected to the global I/O line pair, wherein the common local sense amplifier may include a first NMOS transistor having a first terminal connected to the common local I/O line and a gate connected to the complementary common local I/O line, a second NMOS transistor having a first terminal connected to the complementary common local I/O line, a second terminal connected to a second terminal of the first NMOS transistor, and a gate connected to the common local I/O line, a third NMOS transistor, which is turned on in response to a first activation signal applied to a gate of the third NMOS transistor, having a first terminal connected to a ground voltage line and a second terminal connected to the second terminals of the first and second NMOS transistors, a first PMOS transistor having a first terminal connected to the common local I/O line and a gate connected to the complementary common local I/O line, a second PMOS transistor having a first terminal connected to the complementary common local I/O line, a second terminal connected to a second terminal of the first PMOS transistor, and a gate connected to the common local I/O line, and a third PMOS transistor, which is turned on in response to a second activation signal applied to a

gate of the third PMOS transistor, having a first terminal connected to an internal power line and a second terminal connected to the second terminals of the first and second PMOS transistors. In some embodiments, a peripheral circuit, may include a first bit line sense amplifier connected to a first sub cell array of a cell array, a second bit line sense amplifier connected to a second sub cell array of the cell array, a first local I/O line pair electrically connected to a first bit line pair connected to the first bit line sense amplifier, a second local I/O line pair electrically connected to a second bit line pair connected to the second bit line sense amplifier, a first common local I/O line pair connected to the first local I/O line pair and the second local I/O line pair, a first common local sense amplifier configured to amplify a voltage level transferred from the first common local I/O line pair, a global I/O line pair connected to the first common local sense amplifier, and an I/O sense amplifier electrically connected to the global I/O line pair, wherein the peripheral circuit is disposed below or above the cell array. According to various embodiments of the present disclosure, parasitic resistance and/or parasitic capacitance associated with the global I/O line pair are effectively reduced, and a stable voltage level may be rapidly established during read and write operations.

According to various embodiments of the present disclosure, a bottleneck in data transfer using the global I/O line pair may be reduced, and data transfer speed may be improved by reducing loading of the global I/O line pair.

According to various embodiments of the present disclosure, by integrating a plurality of local sense amplifiers into a single common local sense amplifier, the transistor size in the common local sense amplifier and/or a switch circuit may be enlarged in the same device layout area, thereby further improving data transfer speed.

According to various embodiments of the present disclosure, sufficient sensing amplification strength can be secured without arranging a local sense amplifier for every local I/O line, thereby realizing a memory core structure that supports high speed operation while alleviating overall memory chip size increase.

The technical effects obtainable from the present disclosure are not limited to those described above. Other technical effects not mentioned will be clearly understood by those of ordinary skill in the art from the description below.

### BRIEF DESCRIPTION OF THE DRAWINGS

FIG. 1 is a block diagram illustrating a memory device according to embodiments of the present disclosure.

FIGS. 2 and 3 are diagrams illustrating connection structures of a bit line sense amplifier and a local sense amplifier of FIG. 1.

FIG. 4 is a perspective view illustrating a memory core circuit according to embodiments of the present disclosure.

FIG. 5 is a block diagram illustrating a detailed structure of a row decoder of FIG. 1.

FIG. 6 is a diagram for explaining an example of operations of sub cell arrays and sub-row decoders of FIG. 5.

FIG. 7 is a diagram illustrating an example of sub-peripheral circuits, which are part of the peripheral circuit of FIG. 4.

FIG. 8 is a diagram illustrating in more detail circuit structures disposed in the sub-peripheral circuits and the sub-peripheral circuits themselves.

FIG. 9 is a diagram illustrating an example in which the sub-peripheral circuits of FIG. 7 are further arranged.

FIG. 10 is a diagram illustrating in greater detail a portion of the sub-peripheral circuit of FIG. 9.

FIG. 11 is a diagram for explaining an implementation example of the plurality of switching elements of FIG. 8.

FIG. 12 is a diagram illustrating an example of a detailed structure of the common local sense amplifier and a switch circuit of FIG. 8.

FIG. 13 is a diagram illustrating an example in which a voltage level transferred from the common local I/O line pair is amplified according to another embodiment of the disclosure.

FIG. 14 is a circuit diagram for explaining a data flow during a read operation or a write operation for a memory cell.

FIG. 15 is a waveform diagram illustratively showing level changes and timing relationships of main control signals during a read operation in a circuit according to embodiments of the present disclosure.

FIG. 16 is a waveform diagram illustratively showing level changes and timing relationships of main control signals during a write operation in a circuit according to embodiments of the present disclosure.

FIG. 17 is a diagram illustrating an example of a sub-peripheral circuit, which is part of the peripheral circuit of FIG. 4.

FIG. 18 is a diagram illustrating in more detail circuit structures disposed in the sub-peripheral circuits.

### DETAILED DESCRIPTION

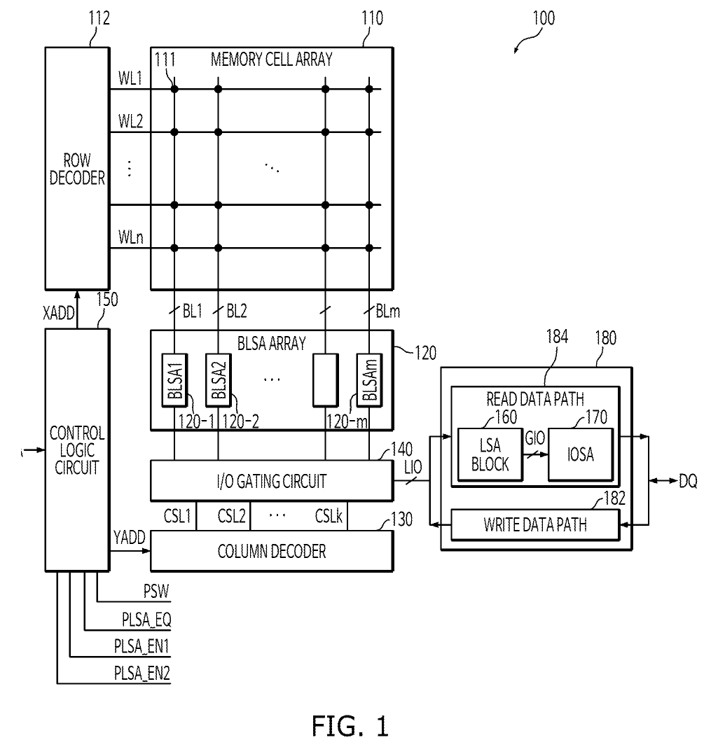

Hereinafter, various embodiments of the present disclosure will be described with reference to FIGS. 1-18. Throughout the entire specification, identical reference numerals may denote identical components.

FIG. 1 is a block diagram illustrating a memory device 100 according to embodiments of the present disclosure.

Referring to FIG. 1, the memory device 100 may include a cell array (e.g., a memory cell array) 110, a row decoder 112, a bit line sense amplifier array (BLSA) 120, a column decoder 130, an input/output (I/O) gating circuit 140, a control logic circuit 150, and a data input/output circuit 180.

The memory cell array 110 may include a plurality of memory cells 111 provided in a matrix arrangement of rows and columns. The memory cell array 110 may include a plurality of word lines WL1~WLn (where n is an integer of 2 or greater) connected to the rows of the memory cells and a plurality of bit lines BL1~BLm (where m is an integer of 2 or greater) connected to the columns of the memory cells. Data of the memory cells connected to an activated word line WL may be sensed and amplified by bit line sense amplifiers connected to the bit lines BL.

The row decoder 112 may decode a row address XADD and activate a word line WL corresponding to the row address XADD among the word lines WL1~WLn. When the word line is activated (e.g., when a word line enable operation is performed), a high voltage VPP higher than a supply voltage VDD may be applied to a gate of an access transistor of the memory cell.

The bit line sense amplifier array 120 may include bit line sense amplifiers 120-1~120-m implemented in an array form. Each of the bit line sense amplifiers 120-1~120-m may sense and amplify data output from the corresponding memory cells 111. The bit line sense amplifier 120-1 may be connected to a bit line pair including a bit line and a complementary bit line to sense and amplify a voltage appearing on the bit line. In the present embodiment, the bit line BL may indicate a bit line pair in a folded bit line sense amplifier type. Each of the bit line sense amplifiers 120-1~120-m may be a cross coupled differential sense amplifier implemented with P-type sense amplifiers and N-type sense amplifiers.

The column decoder 130 may decode a column address YADD and generate column select signals CSL1~CSLk (where k is an integer of 2 or greater). In burst mode, the column decoder 130 may generate the column select signal CSL1~CSLk by decoding a burst address that is gradually incremented by +1 based on the column address YADD, and may connect bit lines BL selected by the column select signals CSL1~CSLk to the I/O gating circuit 140. The burst address may denote addresses of column locations that can be accessed with respect to a burst length for a read and/or write command.

A column select transistor in the I/O gating circuit 140 may transfer a voltage level output from selected bit lines among bit lines BL1~BLm, which are sensed and amplified by the bit line sense amplifiers 120-1~120-m, to a local sense amplifier (LSA) block 160 in response to the column select signals CSL1~CSLk.

The control logic circuit 150 may control circuits of the memory device 100 to perform operations according to control parameters stored in a mode register of the memory device 100. The control logic circuit 150 may receive command/address (CA) signals from a processor or a memory controller. The control logic circuit 150 may receive CA signals indicating read and/or write commands from the memory controller and may control operations according to the read and/or write commands. The control logic circuit 150 may generate control signals (e.g., XADD, YADD, PSW, PLSA_EQ, PLSA_EN1, PLSA_EN2) that control operation timing and/or memory operations of the memory device 100 in response to the CA signals. Depending on the embodiment, commands and addresses may be provided as separate signals.

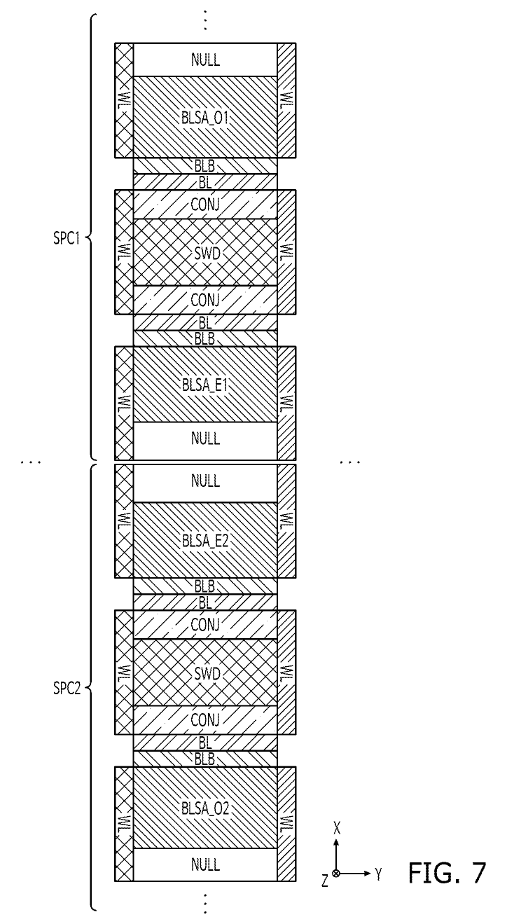

The control logic circuit 150 may control levels of signals (e.g., activation signals, block select signals, column select signals, drive signals, and similar signals) that will be described below with reference to FIGS. 7-18.

The data input/output circuit 180 may be divided into a write data path 182 and a read data path 184. The write data path 182 may include data input buffers that receive write data DQ. The read data path 184 may include data output buffers that transmit read data DQ. The read data path 184 may include a local sense amplifier block 160 and an I/O sense amplifier (IOSA) 170 that output read data DQ. The local sense amplifier block 160 may include one or more local sense amplifiers that amplify a voltage level transferred through a local I/O line pair LIO, LIOB, and the I/O sense amplifier 170 may amplify a voltage level transferred through a global I/O line pair GIO, GIOB.

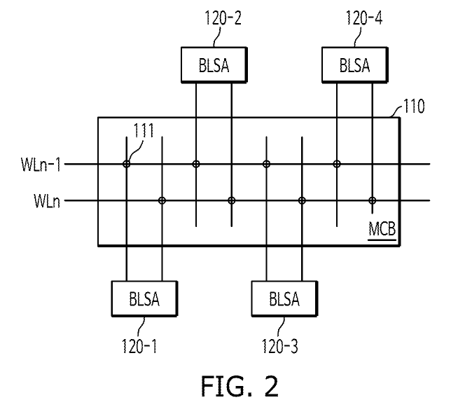

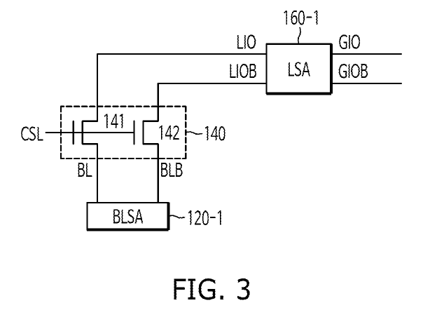

FIGS. 2 and 3 are diagrams illustrating connection structures of the bit line sense amplifier BLSA and the local sense amplifier LSA of FIG. 1. FIG. 2 illustrates a connection structure of the bit line sense amplifier, and FIG. 3 may illustrate a connection structure between the bit line sense amplifier and the local sense amplifier. The bit line sense amplifiers 120-1~120-4 of FIG. 2 and the bit line sense amplifier 120-1 of FIG. 3 may be included in the bit line sense amplifier array 120 of FIG. 1, and the local sense amplifier 160-1 of FIG. 3 may be included in the local sense amplifier block 160 of FIG. 1.

Referring to FIG. 2, a plurality of bit lines (e.g., four bit line pairs) of memory cells 111, which is connected to word lines WLn -1, WLn (where n is an integer of 2 or greater) inside the memory cell array 110 may be connected to the bit line sense amplifiers 120-1~120-4 inside the bit line sense amplifier array 120. The memory cell array 110 may include a plurality of memory banks, and each memory bank may include a plurality of memory cell blocks MCB.

Referring to FIG. 3, the local sense amplifier 160-1 may amplify a voltage level transferred through the local I/O line pair LIO, LIOB and may output the amplified level to the global I/O line pair GIO, GIOB. The global I/O line pair GIO, GIOB may be connected to data pins through the I/O sense amplifier (e.g., item 170 in FIG. 1) and a data output buffer. The bit line pair BL, BLB connected to the bit line sense amplifier 120-1 may be connected to the local I/O line pair LIO, LIOB through column select transistors 141, 142. The column select transistors 141, 142 may electrically connect the bit line pair BL, BLB to the local I/O line pair LIO, LIOB in response to a column select signal CSL.

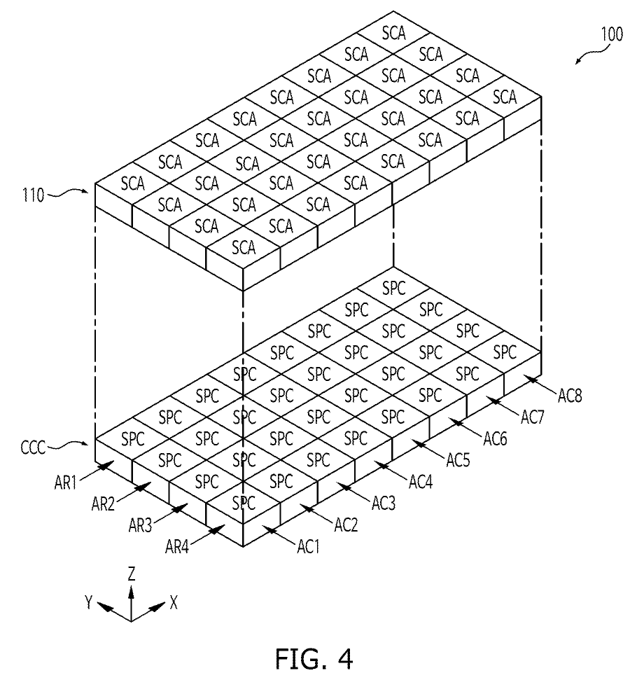

FIG. 4 is a perspective view illustrating a memory core circuit according to embodiments of the present disclosure.

In FIG. 4, a direction substantially perpendicular to an upper surface of a semiconductor substrate may be defined as a vertical direction Z, and two directions parallel to the upper surface of the semiconductor substrate and crossing each other may be defined as a row direction X and a column direction Y, respectively. For example, the row direction X and the column direction Y may cross each other substantially perpendicularly. The row direction X may also be called a first direction or a first horizontal direction, the column direction Y may also be called a second direction or a second horizontal direction, and the vertical direction Z may be called a third direction. Directions indicated by arrows in the drawing and opposite directions thereof may be described as the same directions.

Referring to FIG. 4, the memory device 100 may include the memory cell array 110 and a peripheral circuit CCC. The memory device 100 may have a cell on periphery (CoP) structure in which the peripheral circuit CCC is disposed below (e.g., in a –Z direction) the memory cell array 110. Alternatively, the memory device 100 may have a periphery on cell (PoC) structure in which the peripheral circuit CCC is disposed above (e.g., in a +Z direction) the memory cell array 110.

The memory cell array 110 may include a plurality of sub cell arrays SCA arranged in a matrix of a plurality of array rows AR1~AR4 and a plurality of array columns AC1~AC8.

The peripheral circuit CCC may include components other than the memory cell array 110 in FIG. 1. The peripheral circuit CCC may include a plurality of sub-peripheral circuits SPC that are respectively disposed below the plurality of sub cell arrays SCA in the matrix of the plurality of array rows AR1~AR4 and the plurality of array columns AC1~AC8 and respectively control operations of the plurality of sub cell arrays SCA. In addition to the plurality of sub-peripheral circuits SPC corresponding to the plurality of sub cell arrays SCA, the peripheral circuit CCC may include a circuit associated with the entire memory cell array 110 or with two or more sub-peripheral circuits SPC.

Each sub cell array SCA may include a plurality of memory cells connected respectively to word lines extending in the row direction X and arranged in the column direction Y, and to bit lines extending in the column direction Y and arranged in the row direction X. Each of the plurality of memory cells may include a transistor and a cell capacitor.

For convenience of illustration and description, FIG. 4 shows thirty-two sub cell arrays SCA disposed in four array rows AR1~AR4 and eight array columns AC1~AC8, and thirty-two corresponding sub-peripheral circuits SPC, but embodiments of the present disclosure are not limited to a particular number of array rows or array columns.

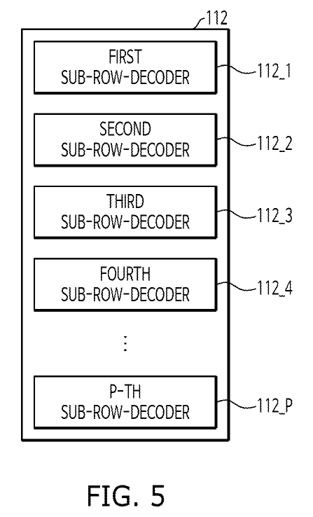

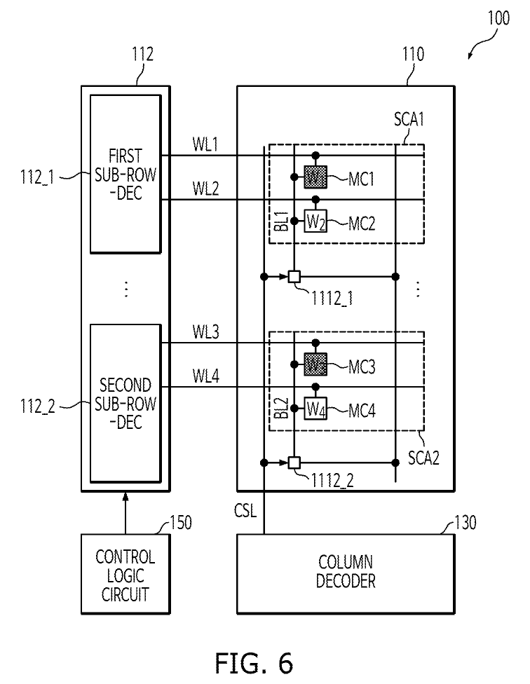

FIG. 5 is a block diagram illustrating a detailed structure of the row decoder 112 of FIGS. 1 and 6 is a diagram for explaining an example of operations of sub-row decoders 112_1, 112_2 and sub cell arrays SCA1, SCA2 of FIG. 5.

Referring to FIGS. 1 and 5, the row decoder 112 may include a plurality of sub-row decoders 112_1~112_P (where P is an integer of 2 or greater). Each of the plurality of sub-row decoder 112_1~112_P may be connected to a portion of the memory cells of the memory cell array 110.

Referring to FIG. 6, the memory cell array 110 may include the sub cell arrays SCA1 and SCA2. All memory cells of the memory cell array 110 may be divided into sub cell arrays such as the sub cell arrays SCA1 and SCA2. For convenience of description, two sub cell arrays SCA1, SCA2 are illustrated in FIG. 6, but the number is not limited thereto. For example, as shown in FIG. 4, the memory cell array 110 may include a plurality of sub cell arrays arranged in a matrix.

The sub cell array SCA1 may include memory cells MC1 and MC2 (e.g., “W₁” and “W₂” in FIG. 6). The memory cells MC1 and MC2 may be connected respectively to word lines WL1 and WL2 and may be commonly connected to a bit line BL1. The sub cell array SCA2 may include memory cells MC3 and MC4 (e.g., “W₃” and “W₄” in FIG. 6). The memory cells MC3 and MC4 may be connected respectively to word lines WL3 and WL4 and may be commonly connected to a bit line BL2.

The memory cell array 110 may include a column select switch 1112_1 that electrically connects the bit line BL1 to an I/O line IO. The column select switch 1112_1 may electrically connect the bit line BL1 to the I/O line IO based on a column select signal. The memory cell array 110 may include a column select switch 1112_2 that electrically connects the bit line BL2 to the I/O line IO. The column select switch 1112_2 may electrically connect the bit line BL2 to the I/O line IO based on a column select signal CSL. For example, the column select switches 1112_1 and 1112_2 may be connected respectively to the same column select line and may receive the same column select signal through the same column select line. The column select signal may electrically connect the bit lines BL1 and BL2, respectively, to the same I/O line.

In an embodiment, the numbers of sub cell arrays in the memory cell array 110, the numbers of memory cells per sub cell array, the numbers of word lines, and the numbers of bit lines are all merely illustrative. In addition, the same number of bit line sense amplifiers as the number of bit lines per sub cell array SCA1 may be disposed adjacent to the sub cell array SCA1 (and likewise for the sub cell array SCA2). The column select switches 1112_1 and 1112_2 may be disposed between the sub cell arrays SCA1 and SCA2. The sub cell array SCA1 may be disposed between other bit line sense amplifiers adjacent to the sub cell array SCA1. The memory cells MC1~MC4 may be implemented identically to each other, the sub cell arrays SCA1 and SCA2 may be implemented identically to each other, and the column select switches 1112_1 and 1112_2 may be implemented identically to each other.

The row decoder 112 may decode an internal row address and may select at least one of the word lines WL1~WL4 connected to the memory cells MC1~MC4 of the memory cell array 110.

The row decoder 112 may include the sub-row decoders 112_1 and 112_2. For example, the sub-row decoder 112_1 may decode an internal row address and may select one of the word lines WL1 and WL2 connected to the sub cell array SCA1. For example, the sub-row decoder 112_2 may decode an internal row address and may select one of the word lines WL3 and WL4 connected to the sub cell array SCA2. The sub-row decoders 112_1 and 112_2 may be implemented identically. The row decoder 112 may include as many sub-row decoders as the number of sub cell arrays of the memory cell array 110.

The row decoder 112 may decode an internal row address to select the word lines WL2 and WL4, and the column decoder 130 may decode an internal column address to select a column select line. For example, the row decoder 112 and the column decoder 130 may sequentially select the memory cells MC1 and MC3 and then the memory cells MC2 and MC4.

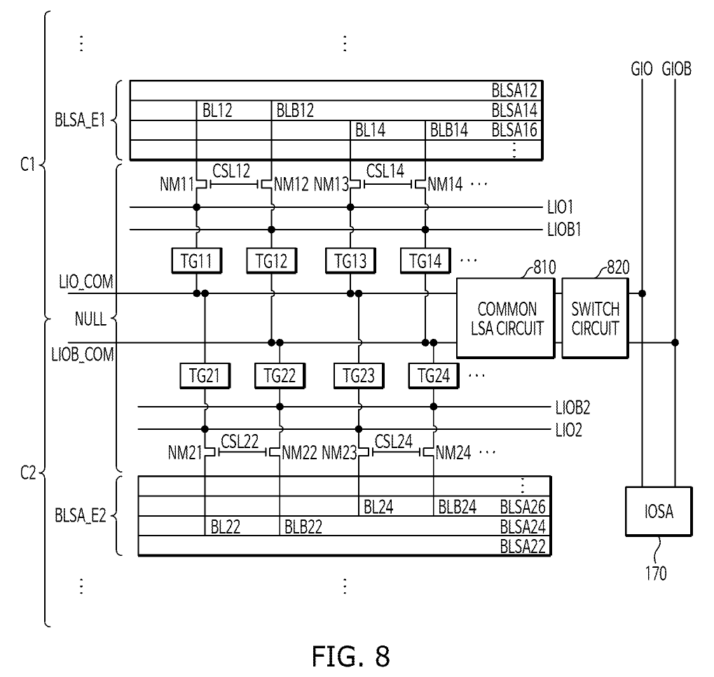

FIG. 7 is a diagram illustrating an example of sub-peripheral circuits SPC1 and SPC2, which are part of the peripheral circuit CCC of FIGS. 4 and 8, is a diagram illustrating in greater detail the circuit structures disposed in the sub-peripheral circuits SPC1 and SPC2.

Referring to FIGS. 4 and 7, each sub-peripheral circuit SPC1, SPC2 may be a circuit connected to a respective one of the sub cell arrays SCA in the memory cell array 110 of FIG. 4. For example, the first sub-peripheral circuit SPC1 may be connected to a first sub cell array, which is one of the sub cell arrays SCA of the memory cell array 110 (e.g., SCA1 in FIG. 6), and the second sub-peripheral circuit SPC2 may be connected to a second sub cell array, which is another of the sub cell arrays SCA of the memory cell array 110 (e.g., SCA2 in FIG. 6). The first sub-peripheral circuit SPC1 may be disposed above or below (e.g., in the +Z or –Z direction) the first sub cell array, and the second sub-peripheral circuit SPC2 may be disposed above or below (e.g., in the +Z or –Z direction) the second sub cell array.

Each of sub-peripheral circuit SPC1, SPC2 may include bit line sense amplifier regions (e.g., the sub-peripheral circuit SPC1 may include bit line sense amplifier regions BLSA_O1, BLSA_E1, and the sub-peripheral circuit SPC2 may include bit line sense amplifier regions BLSA_O2, BLSA_E2), sub-word line driver regions SWD, conjunction regions CONJ, and null regions NULL.

The bit line sense amplifier regions BLSA_O1, BLSA_E1, BLSA_O2, BLSA_E2 may be connected respectively to the sub cell arrays connected to the sub-peripheral circuits SPC1 and SPC2. For example, the bit line sense amplifier regions BLSA_O1 and BLSA_E1 of the first sub-peripheral circuit SPC1 may be connected to the first sub cell array through bit line pairs BL, BLB, and the bit line sense amplifier regions BLSA_O2 and BLSA_E2 of the second sub-peripheral circuit SPC2 may be connected to the second sub cell array through bit line pairs BL, BLB.

Each of bit line sense amplifier region BLSA_O1, BLSA_E1, BLSA_O2, BLSA_E2 may include a plurality of bit line sense amplifiers. Each of bit line sense amplifier region BLSA_O1, BLSA_E1, BLSA_O2, BLSA_E2 may be connected to a sub cell array through bit line pairs BL, BLB that are disposed adjacent to the respective bit line sense amplifier region.

In an example, one sub-peripheral circuit may include two bit line sense amplifier regions. For example, the bit line sense amplifier regions BLSA_O1 and BLSA_E1 of the first sub-peripheral circuit SPC1 may include a bit line sense amplifier region BLSA_O1 that includes bit line sense amplifiers respectively connected to odd numbered bit line pairs and a bit line sense amplifier region BLSA_E1 that includes bit line sense amplifiers respectively connected to even numbered bit line pairs. The bit line sense amplifier regions BLSA_O2 and BLSA_E2 of the second sub-peripheral circuit SPC2 may include a bit line sense amplifier region BLSA_O2 that includes bit line sense amplifiers respectively connected to odd numbered bit line pairs and a bit line sense amplifier region BLSA_E2 that includes bit line sense amplifiers respectively connected to even numbered bit line pairs.

In an example, between adjacent sub-peripheral circuits, bit line sense amplifier regions that include bit line sense amplifiers connected respectively to even numbered bit line pairs may be disposed adjacent to each other, or bit line sense amplifier regions that include bit line sense amplifiers connected respectively to odd numbered bit line pairs may be disposed adjacent to each other. For example, the bit line sense amplifier region BLSA_E1 of the first sub-peripheral circuit SPC1, which includes bit line sense amplifiers connected respectively to even numbered bit line pairs, and the bit line sense amplifier region BLSA_E2 of the second sub-peripheral circuit SPC2, which includes bit line sense amplifiers connected respectively to even numbered bit line pairs, may be disposed adjacent to each other. Contrary to what is shown in FIG. 7, in another embodiment, the bit line sense amplifier region BLSA_O1 of the first sub-peripheral circuit SPC1, which includes bit line sense amplifiers connected respectively to odd numbered bit line pairs, and the bit line sense amplifier region BLSA_O2 of the second sub-peripheral circuit SPC2, which includes bit line sense amplifiers connected respectively to odd numbered bit line pairs, may be disposed adjacent to each other.

Each sub-word line driver region SWD may include sub-word line drivers that respectively drive word lines WL. Each sub-word line driver region SWD may be disposed between the bit line sense amplifier regions in one sub-peripheral circuit. For example, the sub-word line driver region SWD of the first sub-peripheral circuit SPC1 may be disposed between the bit line sense amplifier regions BLSA_O1 and BLSA_E1, and the sub-word line driver region SWD of the second sub-peripheral circuit SPC2 may be disposed between the bit line sense amplifier regions BLSA_O2 and BLSA_E2.

The conjunction regions CONJ may be disposed between bit line sense amplifier regions within one sub-peripheral circuit. For example, the conjunction regions CONJ of the first sub-peripheral circuit SPC1 may be disposed between the bit line sense amplifier regions BLSA_O1 and BLSA_E1, and the conjunction regions CONJ of the second sub-peripheral circuit SPC2 may be disposed between the bit line sense amplifier regions BLSA_O2 and BLSA_E2. Within one sub-peripheral circuit, the sub-word line driver region SWD may be disposed between conjunction regions CONJ within the same sub-peripheral circuit.

Each conjunction region CONJ may include a circuit that assists operations of the sub-word line driver region SWD and/or the bit line sense amplifier regions BLSA_O1, BLSA_E2, BLSA_O2, or BLSA_E2. For example, each conjunction region CONJ may include a transistor that supplies (or additionally supplies) power to the bit line sense amplifier regions BLSA_O1, BLSA_E2, BLSA_O2, or BLSA_E2 and an inverter that lifts a signal when transmitting the signal to the row decoder (e.g., items 112_1 and 112_2 of FIG. 6).

A null region NULL may be a region in which a circuit corresponding to a specific one sub cell array is not disposed. A circuit corresponding to two or more sub cell arrays may be disposed in the null region NULL.

Referring to FIG. 8, the bit line sense amplifier region BLSA_E1 of the first sub-peripheral circuit SPC1 may include a first set of bit line sense amplifiers BLSA12, BLSA14, BLSA16 connected respectively to even numbered (or odd numbered) bit lines, and the bit line sense amplifier region BLSA_E2 of the second sub-peripheral circuit SPC2 may include a second set of bit line sense amplifiers BLSA22, BLSA24, BLSA26 connected respectively to even numbered (or odd numbered) bit lines. The first set of bit line sense amplifiers BLSA12, BLSA14, BLSA16 and the second set of bit line sense amplifiers BLSA22, BLSA24, BLSA26 may all be connected either to even numbered bit line pairs or to odd numbered bit line pairs. For example, the bit line pairs BL12, BLB12, BL14, BLB14, BL22, BLB22, BL24, BLB24 in FIG. 8 may all be even numbered bit line pairs or all odd numbered bit line pairs.

Each of the plurality of bit line sense amplifiers may be connected to a sub cell array through a respective bit line pair. For example, the bit line sense amplifier BLSA12 may be connected to the bit line pair BL12, BLB12, and the bit line sense amplifier BLSA14 may be connected to the bit line pair BL14, BLB14, thereby being connected to the first sub cell array. The bit line sense amplifier BLSA22 may be connected to the bit line pair BL22, BLB22, and the bit line sense amplifier BLSA24 may be connected to the bit line pair BL24, BLB24, thereby being connected to the second sub cell array.

In the null region NULL, a first local I/O line pair LIO1, LIOB1, a second local I/O line pair LIO2, LIOB2, a common local I/O line pair LIO_COM, LIOB_COM, a plurality of switching elements TG11~TG14, TG21~TG24, a common local sense amplifier 810, and a switch circuit 820 may be disposed. However, the configuration is not limited thereto, and some components or a part of a specific component may be disposed outside the null region NULL.

The first local I/O line pair LIO1, LIOB1 may be electrically connected to the first set of bit line sense amplifiers BLSA12, BLSA14, BLSA16 in the bit line sense amplifier region BLSA_E1 of the first sub-peripheral circuit SPC1. For example, the first local I/O line pair LIO1, LIOB1 may be electrically connected to the bit line pair BL12, BLB12 and the bit line pair BL14, BLB14 connected respectively to the bit line sense amplifiers BLSA12 and BLSA14 of the first set of bit line sense amplifiers BLSA12, BLSA14, BLSA16 in the bit line sense amplifier region BLSA_E1.

The first local I/O line pair LIO1, LIOB1 may include a first local I/O line LIO1 and a first complementary local I/O line LIOB1. The first local I/O line LIO1 may be connected to the bit lines BL12, BL14, and the first complementary local I/O line LIOB1 may be connected to the complementary bit lines BLB12, BLB14.

In an embodiment, the first set of bit line sense amplifiers BLSA12, BLSA14, BLSA16 in the bit line sense amplifier region BLSA_E1 of the first sub-peripheral circuit SPC1 may be electrically connected to the first local I/O line pair LIO1, LIOB1 in response to column select transistors NM11, NM12, NM13, NM14 (e.g., N-channel Metal Oxide Semiconductor (NMOS) transistors) that are connected to the first set of bit line sense amplifiers BLSA12, BLSA14, BLSA16 and are turned on by column select signals CSL12, CSL14. In an embodiment, when a read operation or a write operation through a bit line pair is initiated, a column select transistor corresponding to the bit line pair may be turned on. For example, when a read operation or a write operation through the first bit line pair BL12, BLB12 is initiated, the column select transistors NM11, NM12 connected to the first bit line pair BL12, BLB12 may be turned on by the column select signal CSL12, and the other column select transistors NM13, NM14 may be turned off, whereby the bit line sense amplifier BLSA12 may be electrically connected to the first local I/O line pair LIO1, LIOB1.

The second local I/O line pair LIO2, LIOB2 may be electrically connected to the second set of bit line sense amplifiers BLSA22, BLSA24, BLSA26 in the bit line sense amplifier region BLSA_E2 of the second sub-peripheral circuit SPC2. For example, the second local I/O line pair LIO2, LIOB2 may be electrically connected to the bit line pair BL22, BLB22 and the bit line pair BL24, BLB24 connected respectively to the bit line sense amplifiers BLSA22 and BLSA24 of the second set of bit line sense amplifiers BLSA22, BLSA24, BLSA26 in the bit line sense amplifier region BLSA_E2.

The second local I/O line pair LIO2, LIOB2 may include a second local I/O line LIO2 and a second complementary local I/O line LIOB2. The second local I/O line LIO2 may be connected to the bit lines BL22, BL24, and the second complementary local I/O line LIOB2 may be connected to the complementary bit lines BLB22, BLB24.

The second set of bit line sense amplifiers BLSA22, BLSA24, BLSA26 in the bit line sense amplifier region BLSA_E2 of the second sub-peripheral circuit SPC2 may be electrically connected to the second local I/O line pair LIO2, LIOB2 in response to the column select transistors NM21, NM22, NM23, NM24 (e.g., NMOS transistors) being turned on by column select signals CSL22, CSL24. For example, when a read operation or a write operation through a bit line pair is initiated, the column select transistor corresponding to the bit line pair may be turned on. Specifically, when a read operation or a write operation through the second bit line pair BL22, BLB22 is initiated, the column select transistors NM21, NM22 connected to the second bit line pair BL22, BLB22 may be turned on by the column select signal CSL22, and the other column select transistors NM23, NM24 may be turned off, whereby the bit line sense amplifier, such as BLSA22, may be electrically connected to the second local I/O line pair LIO2, LIOB2.

The common local I/O line pair LIO_COM, LIOB_COM may be connected to the first local I/O line pair LIO1, LIOB1 and the second local I/O line pair LIO2, LIOB2.

The common local I/O line pair LIO_COM, LIOB_COM may include a common local I/O line LIO_COM and a complementary common local I/O line LIOB_COM. The common local I/O line LIO_COM may be connected to the first local I/O line LIO1 and the second local I/O line LIO2, and the complementary common local I/O line LIOB_COM may be connected to the first complementary local I/O line LIOB1 and the second complementary local I/O line LIOB2.

The plurality of switching elements TG11~TG14, TG21~TG24 may electrically connect the common local I/O line pair LIO_COM, LIOB_COM to one of the first local I/O line pair LIO1, LIOB1 and the second local I/O line pair LIO2, LIOB2, and may electrically isolate (e.g., electrically disconnect) the common local I/O line pair LIO_COM, LIOB_COM from the other of the first local I/O line pair LIO1, LIOB1 and the second local I/O line pair LIO2, LIOB2. For example, the plurality of switching elements TG11~TG14, TG21~TG24 may include a plurality of first switching elements TG11~TG14 connected to the first local I/O line pair LIO1, LIOB1 and a plurality of second switching elements TG21~TG24 connected to the second local I/O line pair LIO2, LIOB2. The plurality of first switching elements TG11~TG14 may be turned on in response to initiation of a read operation or a write operation for the first sub cell array connected to the first sub-peripheral circuit SPC1, and may be turned off in response to initiation of a read operation or a write operation for the second sub cell array connected to the second sub-peripheral circuit SPC2. The plurality of second switching elements TG21~TG24 may be turned on in response to initiation of a read operation or a write operation for the second sub cell array connected to the second sub-peripheral circuit SPC2, and may be turned off in response to initiation of a read operation or a write operation for the first sub cell array connected to the first sub-peripheral circuit SPC1.

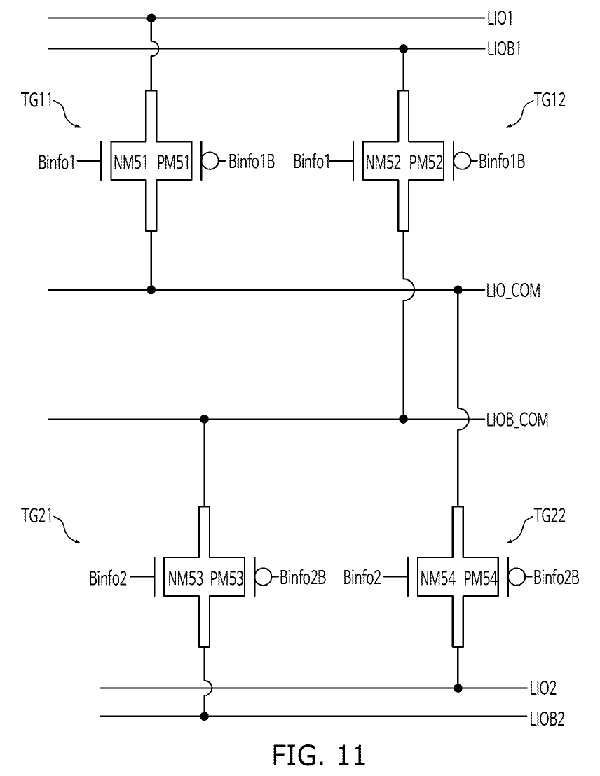

The plurality of switching elements TG11~TG14, TG21~TG24 may include transmission gate circuits. Details thereof will be described below with reference to FIG. 11.

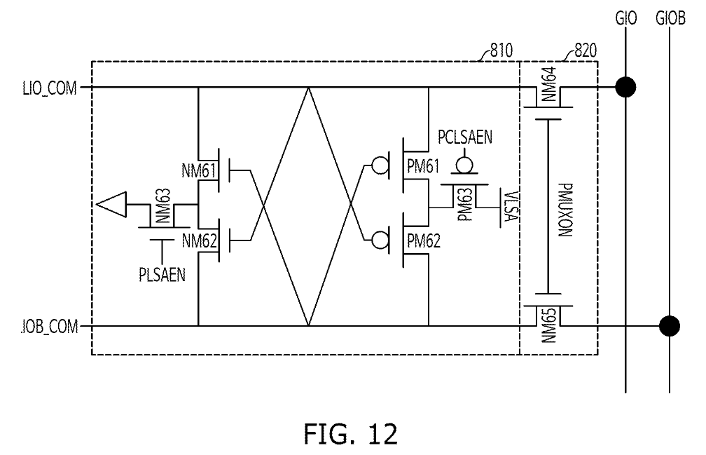

The common local sense amplifier 810 may amplify a voltage level transferred from the common local I/O line pair LIO_COM, LIOB_COM. The common local sense amplifier 810 may be disposed between the bit line sense amplifier region BLSA_E1 of the first sub-peripheral circuit SPC1 connected to the first sub cell array and the bit line sense amplifier region BLSA_E2 of the second sub-peripheral circuit SPC2 connected to the second sub cell array. Details of the common local sense amplifier 810 will be described below with reference to FIG. 12.

The switch circuit 820 may electrically connect the common local sense amplifier 810 and the global I/O line pair GIO, GIOB in response to initiation of a read operation or a write operation for either the first sub cell array connected to the first sub-peripheral circuit SPC1 or the second sub cell array connected to the second sub-peripheral circuit SPC2. Details of the switch circuit 820 will be described below with reference to FIG. 12.

The global I/O line pair GIO, GIOB may be connected to the common local sense amplifier 810 and the switch circuit 820.

The global I/O line pair GIO, GIOB may include a global I/O line GIO and a complementary global I/O line GIOB. The global I/O line GIO may be connected to the common local I/O line LIO_COM, and the complementary global I/O line GIOB may be connected to the complementary common local I/O line LIOB_COM.

The I/O sense amplifier 170 may be electrically connected to the global I/O line pair GIO, GIOB.

Through the circuit structure described above with reference to FIG. 8, parasitic resistance and/or parasitic capacitance associated with the global I/O line pair GIO, GIOB may be effectively reduced, a bottleneck in data transfer using the global I/O line pair GIO, GIOB may be reduced, and data transfer speed may be improved by reducing loading of the global I/O line pair GIO, GIOB. For example, in a conventional circuit structure, a local sense amplifier is separately provided for each local I/O line pair and connected to the global I/O line pair GIO, GIOB, whereas in the circuit structure according to the present disclosure, a single common local sense amplifier 810 is provided. Thus, compared to the conventional circuit structure the number of transistors directly connected to the global I/O line pair GIO, GIOB in the circuit structure of the present disclosure is reduced, whereby parasitic resistance and/or parasitic capacitance may be reduced. Consequently, the bottleneck of the global I/O line pair GIO, GIOB may be reduced and data transfer speed may be improved. In addition, by integrating a plurality of local sense amplifiers into the single common local sense amplifier 810, the transistor size of the common local sense amplifier 810 and/or the switch circuit 820 may be enlarged within the same device layout area, thereby further improving data transfer speed.

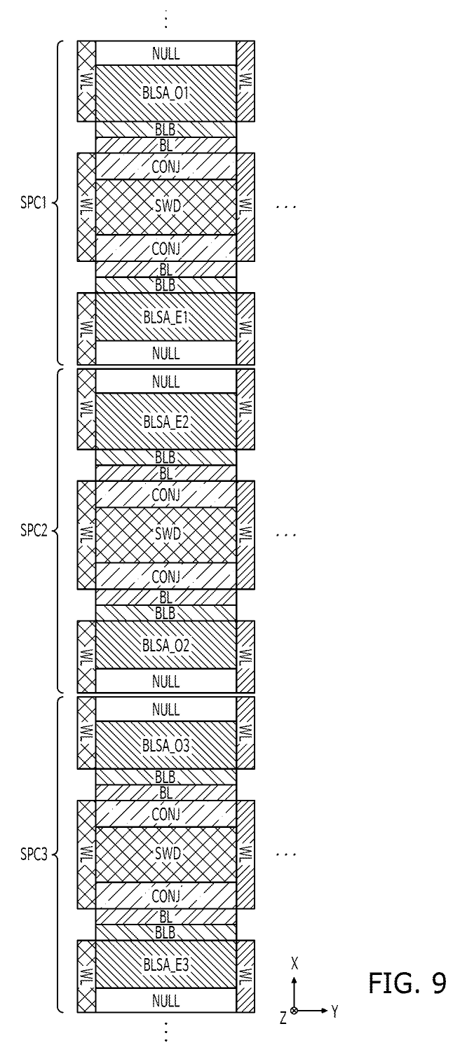

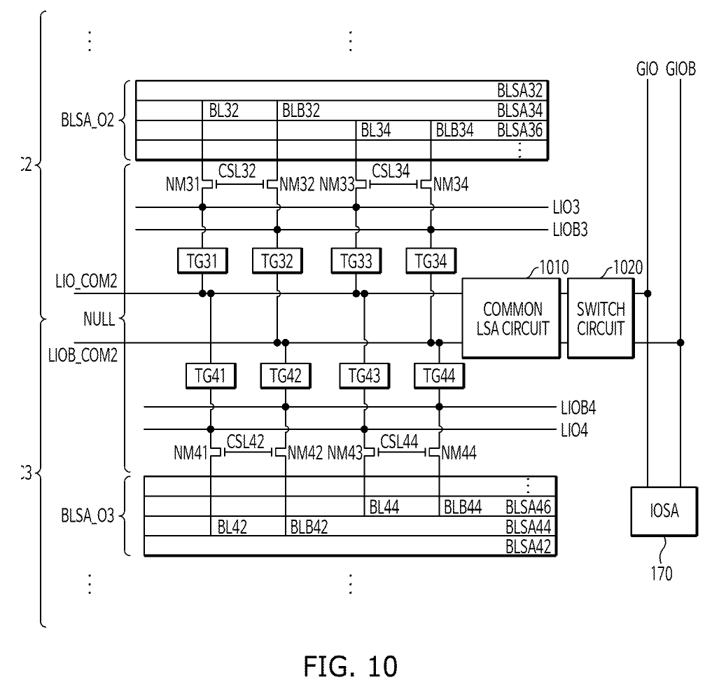

FIG. 9 is a diagram illustrating an example in which a sub-peripheral circuit is additionally disposed as shown in FIGS. 7 and 10 is a diagram illustrating, in greater detail, a portion of the sub-peripheral circuit of FIG. 9.

Referring to FIG. 9, a third sub-peripheral circuit SPC3 may be a circuit connected to any one of the sub cell arrays SCA of the cell array 110 of FIG. 4 other than the sub cell arrays connected respectively to the first sub-peripheral circuit SPC1 and the second sub-peripheral circuit SPC2. The third sub-peripheral circuit SPC3 may be disposed above or below (e.g., in the +Z or –Z direction) a third sub cell array.

The third sub-peripheral circuit SPC3 may include bit line sense amplifier regions BLSA_O3 and BLSA_E3, a sub-word line driver region SWD, a conjunction region CONJ, and null regions NULL.

The bit line sense amplifier regions BLSA_O3 and BLSA_E3 of the third sub-peripheral circuit SPC3 may be connected to the sub cell array connected to the third sub-peripheral circuit SPC3. For example, the bit line sense amplifier regions BLSA_O3 and BLSA_E3 of the third sub-peripheral circuit SPC3 may be connected to the third sub cell array through bit line pairs BL and BLB. Each of bit line sense amplifier region BLSA_O3, BLSA_E3 may include a plurality of bit line sense amplifiers. Each of bit line sense amplifier region BLSA_O3, BLSA_E3 may be connected to the sub cell array through bit line pairs BL and BLB disposed adjacent to the respective bit line sense amplifier region.

The bit line sense amplifier regions BLSA_O3 and BLSA_E3 of the third sub-peripheral circuit SPC3 may include a bit line sense amplifier region BLSA_O3 that includes bit line sense amplifiers respectively connected to odd numbered bit line pairs and a bit line sense amplifier region BLSA_E3 that includes bit line sense amplifiers respectively connected to even numbered bit line pairs.

The bit line sense amplifier region BLSA_O2, which is connected to odd numbered bit lines in the second sub-peripheral circuit SPC2, and the bit line sense amplifier region BLSA_O3, which is connected to odd numbered bit lines in the third sub-peripheral circuit SPC3, may be disposed adjacent to each other. Alternatively, when the bit line sense amplifier region BLSA_O1 connected to odd numbered bit lines in the first sub-peripheral circuit SPC1 and the bit line sense amplifier region BLSA_O2 connected to odd numbered bit lines in the second sub-peripheral circuit SPC2 are disposed adjacent to each other, the bit line sense amplifier region BLSA_E2 connected to even numbered bit lines in the second sub-peripheral circuit SPC2 and the bit line sense amplifier region BLSA_E3 connected to even numbered bit lines in the third sub-peripheral circuit SPC3 may be disposed adjacent to each other.

The sub-word line driver region SWD of the third sub-peripheral circuit SPC3 may be disposed between the bit line sense amplifier regions BLSA_O3 and BLSA_E3.

The conjunction regions CONJ of the third sub-peripheral circuit SPC3 may be disposed between the bit line sense amplifier regions BLSA_O3 and BLSA_E3. The sub-word line driver region SWD of the third sub-peripheral circuit SPC3 may be disposed between conjunction regions CONJ of the third sub-peripheral circuit SPC3.

Referring to FIG. 10, the bit line sense amplifier region BLSA_O2 of the second sub-peripheral circuit SPC2 may include a third set of bit line sense amplifiers BLSA32, BLSA34, BLSA36 connected respectively to odd numbered bit lines, and the bit line sense amplifier region BLSA_O3 of the third sub-peripheral circuit SPC3 may include a fourth set of bit line sense amplifiers BLSA42, BLSA44, BLSA46 connected respectively to odd numbered bit lines. The third set of bit line sense amplifiers BLSA32, BLSA34, BLSA36 and the fourth set of bit line sense amplifiers BLSA42, BLSA44, BLSA46 may all be connected to odd numbered bit line pairs. Conversely, when the first set of bit line sense amplifiers BLSA12, BLSA14, BLSA16 and the second set of bit line sense amplifiers BLSA22, BLSA24, BLSA26 described above with reference to FIG. 8 are all connected to odd numbered bit line pairs, the third set of bit line sense amplifiers BLSA32, BLSA34, BLSA36 and the fourth set of bit line sense amplifiers BLSA42, BLSA44, BLSA46 may all be connected to even numbered bit line pairs. For example, the bit line pair BL32, BLB32, the bit line pair BL34, BLB34, the bit line pair BL42, BLB42, the bit line pair BL44, BLB44 of FIG. 10 may all be even numbered bit line pairs or all odd numbered bit line pairs.

Each of the plurality of bit line sense amplifiers may be connected to a bit line pair. Each of the plurality of bit line sense amplifiers may also be connected to a sub cell array through the bit line pair. For example, the bit line sense amplifier BLSA32 may be connected to the bit line pair BL32, BLB32, and the bit line sense amplifier BLSA34 may be connected to the bit line pair BL34, BLB34, thereby connecting to the second sub cell array. Similarly, the bit line sense amplifier BLSA42 may be connected to the bit line pair BL42, BLB42, and the bit line sense amplifier BLSA44 may be connected to the bit line pair BL44, BLB44, thereby connecting to the third sub cell array.

In the null region NULL, a third local I/O line pair LIO3, LIOB3, a fourth local I/O line pair LIO4, LIOB4, a second common local I/O line pair LIO_COM2, LIOB_COM2, a plurality of switching elements TG31~TG34, TG41~TG44, a common local sense amplifier 1010, and a switch circuit 1020 may be disposed. However, the configuration is not limited thereto, and some components or a part of a specific component may be disposed outside the null region NULL.

The third local I/O line pair LIO3, LIOB3 may be electrically connected to the third set of bit line sense amplifiers BLSA32, BLSA34, BLSA36 in the bit line sense amplifier region BLSA_O2 of the second sub-peripheral circuit SPC2. For example, the third local I/O line pair LIO3, LIOB3 may be electrically connected to the bit line pair BL32, BLB32, and the bit line pair BL34, BLB34 connected respectively to the bit line sense amplifiers BLSA32 and BLSA34 of the third set of bit line sense amplifiers BLSA32, BLSA34, BLSA36 in the bit line sense amplifier region BLSA_O2.

The third local I/O line pair LIO3, LIOB3 may include a third local I/O line LIO3 and a third complementary local I/O line LIOB3. The third local I/O line LIO3 may be connected to the bit lines BL32, BL34, and the third complementary local I/O line LIOB3 may be connected to the complementary bit lines BLB32, BLB34.

In an embodiment, the third set of bit line sense amplifiers BLSA32, BLSA34, BLSA36, located in the bit line sense amplifier region BLSA_O2 of the second sub peripheral circuit SPC2, may be electrically connected to the third local I/O line pair LIO3, LIOB3. This occurs in response to the column select transistors NM31, NM32, NM33, NM34 (e.g., NMOS transistors), which are connected to the third set of bit line sense amplifiers BLSA32, BLSA34, BLSA36 and are turned on by column select signals CSL32 and CSL34, respectively. When a read operation or a write operation through a bit line pair is initiated, the column select transistor corresponding to the bit line pair may be turned on. For example, if a read operation or a write operation through the third bit line pair BL32, BLB32 is initiated, the column select transistors NM31 and NM32, connected to this third bit line pair, are turned on by the column select signal CSL32, and consequently, the other column select transistors NM33 and NM34 are turned off. This configuration allows the bit line sense amplifier BLSA32 to be electrically connected to the third local I/O line pair LIO3, LIOB3.

The fourth local I/O line pair LIO4, LIOB4 may be electrically connected to the fourth set of bit line sense amplifiers BLSA42, BLSA44, BLSA46 in the bit line sense amplifier region BLSA_O3 of the third sub-peripheral circuit SPC3. For example, the fourth local I/O line pair LIO4, LIOB4 may be electrically connected to the bit line pair BL42, BLB42, and the bit line pair BL44, BLB44 connected respectively to the bit line sense amplifiers BLSA42 and BLSA44 of the fourth set of bit line sense amplifiers BLSA42, BLSA44, BLSA46 in the bit line sense amplifier region BLSA_O3.

The fourth local I/O line pair LIO4, LIOB4 may include a fourth local I/O line LIO4 and a fourth complementary local I/O line LIOB4. The fourth local I/O line LIO4 may be connected to the bit lines BL42, BL44, and the fourth complementary local I/O line LIOB4 may be connected to the complementary bit lines BLB42, BLB44.

In one embodiment, the fourth set of bit line sense amplifiers (BLSA42, BLSA44, BLSA46) in the bit line sense amplifier region BLSA_O3 of the third sub peripheral circuit SPC3 may be electrically connected to the fourth local I/O line pair (LIO4, LIOB4) in response to column select transistors (NM41, NM42, NM43, NM44) (e.g., NMOS transistors), which are connected to the fourth set of bit line sense amplifiers and are turned on by column select signals (CSL42, CSL44). For instance, when a read or write operation through a bit line pair is initiated, the column select transistor corresponding to the bit line pair may be turned on. Specifically, when a read or write operation through the fourth bit line pair (BL42, BLB42) is initiated, the column select transistors (NM41, NM42) connected to the fourth bit line pair may be turned on by the column select signal CSL42, and other column select transistors (NM43, NM44) may be turned off. Consequently, the bit line sense amplifier (BLSA42) may be electrically connected to the fourth local I/O line pair (LIO4, LIOB4).

The second common local I/O line pair LIO_COM2, LIOB_COM2 may be connected to the third local I/O line pair LIO3, LIOB3 and the fourth local I/O line pair LIO4, LIOB4.

The second common local I/O line pair LIO_COM2, LIOB_COM2 may include a second common local I/O line LIO_COM2 and a second complementary common local I/O line LIOB_COM2. The second common local I/O line LIO_COM2 may be connected to the third local I/O line LIO3 and the fourth local I/O line LIO4, and the second complementary common local I/O line LIOB_COM2 may be connected to the third complementary local I/O line LIOB3 and the fourth complementary local I/O line LIOB4.

The plurality of switching elements TG31~TG34, TG41~TG44 may electrically connect the second common local I/O line pair LIO_COM2, LIOB_COM2 to one of the third local I/O line pair LIO3, LIOB3 and the fourth local I/O line pair LIO4, LIOB4 and may electrically disconnect the second common local I/O line pair LIO_COM2, LIOB_COM2 from the other of the third local I/O line pair LIO3, LIOB3 and the fourth local I/O line pair LIO4, LIOB4. For example, the plurality of switching elements TG31~TG34, TG41~TG44 may include a plurality of third switching elements TG31-TG34 connected to the third local I/O line pair LIO3, LIOB3 and a plurality of fourth switching elements TG41~TG44 connected to the fourth local I/O line pair LIO4, LIOB4. The plurality of third switching elements TG31~TG34 may be turned on in response to initiation of a read operation or a write operation for the sub cell array connected to the second sub peripheral circuit SPC2 and may be turned off in response to initiation of a read operation or a write operation for the sub cell array connected to the third sub peripheral circuit SPC3.

The plurality of fourth switching elements TG41~TG44 may be turned on in response to the initiation of a read operation or a write operation for the third sub-cell array connected to the third sub-peripheral circuit SPC3, and may be turned off in response to the initiation of a read operation or a write operation for the second sub cell array connected to the second sub peripheral circuit SPC2.

The plurality of switching elements TG31~TG34, TG41~TG44 may include transmission gate circuits. The implementation is identical to the embodiment described above with reference to FIG. 8.

The common local sense amplifier 1010 may amplify a voltage level transferred from the second common local I/O line pair LIO_COM2, LIOB_COM2. The common local sense amplifier 1010 may be disposed between the bit line sense amplifier region BLSA_O2 of the second sub-peripheral circuit SPC2 connected to the second sub cell array and the bit line sense amplifier region BLSA_O3 of the third sub-peripheral circuit SPC3 connected to the third sub cell array. The structure of the common local sense amplifier 1010 may correspond to the structure of the common local sense amplifier 810 of FIG. 8.

The switch circuit 1020 may electrically connect the common local sense amplifier 1010 and the global I/O line pair GIO, GIOB in response to initiation of a read operation or a write operation for either the sub cell array connected to the second sub-peripheral circuit SPC2 or the sub cell array connected to the third sub-peripheral circuit SPC3. The structure of the switch circuit 1020 may correspond to the structure of the switch circuit 820 of FIG. 8.

The global I/O line pair GIO, GIOB may be connected to the common local sense amplifier 1010. The global I/O line GIO of the global I/O line pair GIO, GIOB may be further connected to the second common local I/O line LIO_COM2, and the complementary global I/O line GIOB of the global I/O line pair GIO, GIOB may be further connected to the second complementary common local I/O line LIOB_COM2.

The circuit structure illustrated and described with reference to FIGS. 7-10 may be arranged in a repetitive pattern on the peripheral circuit. For example, the circuit structure illustrated and described with reference to FIGS. 7-10 may be repeatedly arranged in the X and Y directions in the peripheral circuit CCC of FIG. 4.

FIG. 11 is a diagram for explaining an implementation example of the plurality of switching elements TG11~TG14 and TG21~TG24 of FIG. 8. In FIG. 11, only some switching elements TG11, TG12, TG21, TG22 among the plurality of switching elements TG11~TG14 and TG21~TG24 of FIG. 8 are illustrated, but the embodiments associated with the switching elements illustrated and described with reference to FIG. 11 may also be applied to the other switching elements TG13, TG14, TG23, TG24 of FIG. 8 and likewise to the plurality of switching elements TG31~TG34 and TG41~TG44 of FIG. 10.

Each of switching element TG11, TG12, TG21, TG22 may be implemented as a transmission gate circuit that selectively electrically connects or disconnects the common local I/O line pair LIO_COM, LIOB_COM to or from the first local I/O line pair LIO1, LIOB1 or the second local I/O line pair LIO2, LIOB2. For example, each of switching element TG11, TG12, TG21, TG22 may be implemented as a circuit that connects, in parallel, a P-channel Metal Oxide Semiconductor (PMOS) transistor and an NMOS transistor, and block select signals Binfo1, Binfo2 and complementary block select signals Binfo1B, Binfo2B may be applied respectively as mutually complementary gate signals to the NMOS and PMOS transistors.

In an example, looking at the switching elements TG11, TG12 connected to the first local I/O line pair LIO1, LIOB1, each of NMOS transistor NM51, NM52 and a respective one of PMOS transistor PM51, PM52 may share both terminals as a common source drain connection, and the block select signal Binfo1 and its complementary block select signal Binfo1B may be applied respectively to gates of the NMOS transistors NM51, NM52 and the PMOS transistors PM51, PM52. Here, when the block select signal Binfo1 is at a “High” (logic 1) state, the switching elements TG11, TG12 may be turned on, whereby the first local I/O line pair LIO1, LIOB1 and the common local I/O line pair LIO_COM, LIOB_COM are electrically connected. Conversely, when the block select signal Binfo1 is at a “Low” (logic 0) state, the switching elements TG11, TG12 may be turned off, whereby the first local I/O line pair LIO1, LIOB1 and the common local I/O line pair LIO_COM, LIOB_COM are electrically disconnected.

In an example, looking at the switching elements TG21, TG22 connected to the second local I/O line pair LIO2, LIOB2, each of NMOS transistor NM53, NM54 and a respective one of PMOS transistor PM53, PM54 may share both terminals as a common source drain connection, and the block select signal Binfo2 and its complementary block select signal Binfo2B may be applied respectively to gates of the NMOS transistors NM53, NM54 and the PMOS transistors PM53, PM54. Here, when the block select signal Binfo2 is at “High,” the switching elements TG21, TG22 may be turned on, whereby the second local I/O line pair LIO2, LIOB2 and the common local I/O line pair LIO_COM, LIOB_COM are electrically connected. Conversely, when the block select signal Binfo2 is at “Low,” the switching elements TG21, TG22 may be turned off, whereby the second local I/O line pair LIO2, LIOB2 and the common local I/O line pair LIO_COM, LIOB_COM are electrically disconnected.

Levels (e.g., High or Low) of the block select signals Binfo1, Binfo2 may be controlled by the control logic circuit (e.g., item 150 of FIG. 1) of the memory device. For example, in response to initiation of a read or write operation for the first sub cell array, the control logic circuit may apply the block select signal Binfo1 at a high level to the switching elements TG11, TG12 to turn them on, thereby connecting the common local I/O line pair LIO_COM, LIOB_COM to the first local I/O line pair LIO1, LIOB1, and may apply the block select signal Binfo2 at a low level to the switching elements TG21, TG22 to turn them off, thereby blocking operations for another sub cell array (e.g., the second sub cell array). Likewise, in response to initiation of a read or write operation for the second sub cell array, the control logic circuit may apply the block select signal Binfo2 at a high level to the switching elements TG21, TG22 to turn them on, thereby connecting the common local I/O line pair LIO_COM, LIOB_COM to the second local I/O line pair LIO2, LIOB2, and may apply the block select signal Binfo1 at a low level to the switching elements TG11, TG12 to turn them off, thereby blocking operations for the other sub cell array (e.g., the first sub cell array).

A unique block select signal Binfo1, Binfo2 may be assigned to each sub cell array; for example, the block select signal Binfo1 may designate the first sub cell array (or the sub-row decoder connected to the first sub cell array), and the block select signal Binfo2 may designate the second sub cell array (or the sub-row decoder connected to the second sub cell array).

According to the embodiments described above, because electrical connection is turned on/off by the transmission gate circuits, the common local I/O line pair LIO_COM, LIOB_COM can be selectively connected only to a local I/O line pair of a required sub cell array. Accordingly, read or write operations can be performed independently without interference among different sub cell arrays, and fast, stable memory operations can be achieved with simple gate control (e.g., the block select signals Binfo1, Binfo2 and complementary block select signals Binfo1B, Binfo2B) that efficiently drive the plurality of switching elements.

FIG. 12 is a diagram illustrating an example of detailed structures of the common local sense amplifier 810 and the switch circuit 820 of FIG. 8. In an embodiment, the detailed structures of the common local sense amplifier 810 and the switch circuit 820 illustrated and described with reference to FIG. 12 may likewise be applied to the common local sense amplifier 1010 and the switch circuit 1020 of FIG. 10.

The common local sense amplifier 810 may include a plurality of NMOS transistors NM61~NM63 and a plurality of PMOS transistors PM61~PM63.

A first terminal of a first NMOS transistor NM61 may be connected to the common local I/O line LIO_COM, and a gate of the first NMOS transistor NM61 may be connected to the complementary common local I/O line LIOB_COM.

A first terminal of a second NMOS transistor NM62 may be connected to the complementary common local I/O line LIOB_COM, a second terminal of the second NMOS transistor NM62 may be connected to a second terminal of the first NMOS transistor NM61, and a gate of the second NMOS transistor NM62 may be connected to the common local I/O line LIO_COM.

A third NMOS transistor NM63 may be turned on in response to application of a first activation signal PLSAEN to its gate; a first terminal of the third NMOS transistor NM63 may be connected to a ground voltage line, and a second terminal of the third NMOS transistor NM63 may be connected to the second terminals of the first and second NMOS transistors NM61 and NM62.

A first terminal of a first PMOS transistor PM61 may be connected to the common local I/O line LIO_COM, and a gate of the first PMOS transistor PM61 may be connected to the complementary common local I/O line LIOB_COM.

A first terminal of a second PMOS transistor PM62 may be connected to the complementary common local I/O line LIOB_COM, a second terminal of the second PMOS transistor PM62 may be connected to a second terminal of the first PMOS transistor PM61, and a gate of the second PMOS transistor PM62 may be connected to the common local I/O line LIO_COM.

A third PMOS transistor PM63 may be turned on in response to application of a second activation signal PCLSAEN to its gate; a first terminal of the third PMOS transistor PM63 may be connected to an internal power line, and a second terminal of the third PMOS transistor PM63 may be connected to the second terminals of the first and second PMOS transistors PM61 and PM62.

By appropriately pulling down or pulling up signals occurring respectively on the common local I/O line LIO_COM and the complementary common local I/O line LIOB_COM through the NMOS transistors NM61~NM63 and the PMOS transistors PM61~PM63 configured as described above, stable read/write operations for internal memory cells or other circuit blocks can be enabled.

For example, on the NMOS transistor side, when the first activation signal PLSAEN is at “High,” the third NMOS transistor NM63 may be turned on to pull down to the ground voltage line an internal node at which the first NMOS transistor NM61 and the second NMOS transistor NM62 are connected.

On the side of the plurality of PMOS transistors (PM61, PM62, PM63), when the second activation signal PCLSAEN is at 'High,' the third PMOS transistor (PM63) may connect the internal power voltage (VLSA) to the PMOS side internal node, allowing the high level (e.g., VDD) to be maintained stably.

In summary, by suitably controlling the NMOS transistors NM61~NM63 and the PMOS transistors PM61~PM63, the common local sense amplifier 810 can actively apply or isolate the voltage level of the common local I/O line pair LIO_COM, LIOB_COM to or from either the ground voltage or the internal power voltage VLSA. This enables fast, stable I/O operations required in memory device or related circuit design and also facilitates signal level initialization when switching operating modes.

The switch circuit 820 may include a first transistor NM64 (e.g., an NMOS transistor) and a second transistor NM65 (e.g., an NMOS transistor).

A first terminal of the first transistor NM64 of the switch circuit 820 may be connected to the common local I/O line LIO_COM, and a second terminal of the first transistor NM64 may be connected to the global I/O line GIO. In response to initiation of a read operation or a write operation for the sub cell array electrically connected to the common local I/O line pair LIO_COM, LIOB_COM, a connection control signal PMUXON may be applied to the gate of the first transistor NM64, whereby the first transistor NM64 may be turned on.

A first terminal of the second transistor NM65 of the switch circuit 820 may be connected to the complementary common local I/O line LIOB_COM, and a second terminal of the second transistor NM65 may be connected to the complementary global I/O line GIOB. In response to initiation of a read operation or a write operation for the sub cell array electrically connected to the common local I/O line pair LIO_COM, LIOB_COM, a connection control signal PMUXON may be applied to the gate of the second transistor NM65, whereby the second transistor NM65 may be turned on.

In an embodiment, the control logic circuit (e.g., item 150 of FIG. 1) of the memory device may control levels (e.g., high or low) of the first activation signal PLSAEN, the second activation signal PCLSAEN, and/or the connection control signal PMUXON.

Through the circuit structure described above with reference to FIG. 12, parasitic resistance and/or parasitic capacitance associated with the global I/O line pair GIO, GIOB may be effectively reduced; a bottleneck in data transfer using the global I/O line pair GIO, GIOB may be reduced; and data transfer speed may be improved by reducing loading of the global I/O line pair GIO, GIOB. For example, compared with a conventional local sense amplifier structure, in the circuit structure according to the present disclosure, only two transistors NM64, NM65 are provided in the switch circuit 820, so the number of transistors directly connected to the global I/O line pair GIO, GIOB is reduced to two, whereby parasitic resistance and/or parasitic capacitance may be reduced. Consequently, the bottleneck of the global I/O line pair GIO, GIOB may be reduced and data transfer speed may be improved.

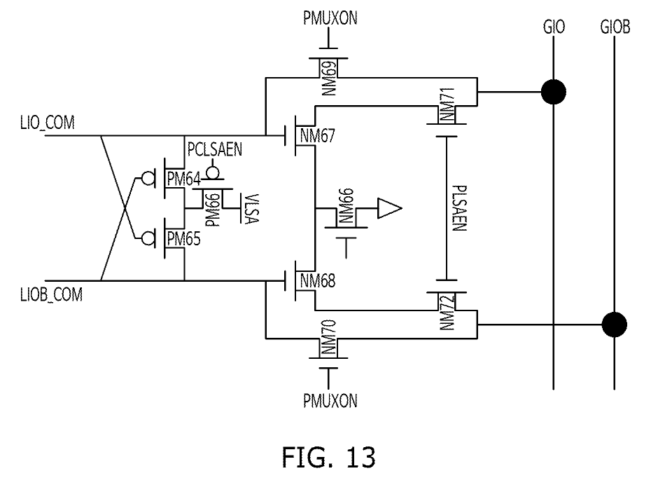

FIG. 13 is a diagram illustrating, according to another embodiment of the present disclosure, an example in which a voltage level transferred from the common local I/O line pair LIO_COM, LIOB_COM is amplified. As an alternative to the structures of the common local sense amplifier 810 and the switch circuit 820 described above with reference to FIGS. 8 and 12, the circuit structure illustrated and described with reference to FIG. 13 may amplify a voltage level transferred from the common local I/O line pair LIO_COM, LIOB_COM and may transfer the amplified level to the global I/O line pair GIO, GIOB. Additionally, the circuit structure illustrated and described with reference to FIG. 13 may alternatively be applied to the common local sense amplifier 1010 and the switch circuit 1020 of FIG. 10.

As an alternative to the structures of the common local sense amplifier 810 and the switch circuit 820 described above with reference to FIGS. 8 and 12, a circuit structure including a plurality of PMOS transistors PM64~PM66 and a plurality of NMOS transistors NM66~NM72 may amplify a voltage level transferred from the common local I/O line pair LIO_COM, LIOB_COM and may transfer the amplified level to the global I/O line pair GIO, GIOB.

A first terminal of a first PMOS transistor PM64 may be connected to the common local I/O line LIO_COM, a gate of the first PMOS transistor PM64 may be connected to the complementary common local I/O line LIOB_COM, and a second terminal of the first PMOS transistor PM64 may be connected to an internal node (hereinafter, “PMOS side common internal node”).

A first terminal of a second PMOS transistor PM65 may be connected to the complementary common local I/O line LIOB_COM, a second terminal of the second PMOS transistor PM65 may be connected to the PMOS side common internal node identical to the second terminal of the first PMOS transistor PM64, and a gate of the second PMOS transistor PM65 may be connected to the common local I/O line LIO_COM.

A third PMOS transistor PM66 may be turned on in response to application of the first activation signal PCLSAEN to its gate; a first terminal of the third PMOS transistor PM66 may be connected to an internal power line, and a second terminal of the third PMOS transistor PM66 may be connected to the PMOS side common internal node.

A first NMOS transistor NM66 may have a first terminal connected to the ground voltage line, a gate connected to the internal power voltage, and a second terminal connected to an internal node (hereinafter, “NMOS side common internal node”).

A first terminal of a second NMOS transistor NM67 may be connected to one terminal (e.g., a second terminal) of a sixth NMOS transistor NM71, a second terminal of the second NMOS transistor NM67 may be connected to the NMOS side common internal node identical to the second terminal of the first NMOS transistor NM66, and a gate of the second NMOS transistor NM67 may be connected to the common local I/O line LIO_COM.

A first terminal of a third NMOS transistor NM68 may be connected to one terminal (e.g., a second terminal) of a seventh NMOS transistor NM72, a second terminal of the third NMOS transistor NM68 may be connected to the NMOS side common internal node, and a gate of the third NMOS transistor NM68 may be connected to the complementary common local I/O line LIOB_COM.

A first terminal of a fourth NMOS transistor NM69 may be connected to the common local I/O line LIO_COM; the fourth NMOS transistor NM69 may be turned on in response to application of the second activation signal PMUXON to its gate; and a second terminal of the fourth NMOS transistor NM69 may be connected to the global I/O line GIO and to one terminal (e.g., a first terminal) of the sixth NMOS transistor NM71.

A first terminal of a fifth NMOS transistor NM70 may be connected to the complementary common local I/O line LIOB_COM; the fifth NMOS transistor NM70 may be turned on in response to application of the second activation signal PMUXON to its gate; and a second terminal of the fifth NMOS transistor NM70 may be connected to the complementary global I/O line GIOB and to one terminal (e.g., a first terminal) of the seventh NMOS transistor NM72.

The sixth NMOS transistor NM71 may be turned on in response to application of a third activation signal PLSAEN to its gate; a first terminal of the sixth NMOS transistor NM71 may be connected to the second terminal of the fourth NMOS transistor NM69, and a second terminal of the sixth NMOS transistor NM71 may be connected to the first terminal of the second NMOS transistor NM67.

The seventh NMOS transistor NM72 may be turned on in response to application of the third activation signal PLSAEN to its gate; a first terminal of the seventh NMOS transistor NM72 may be connected to the second terminal of the fifth NMOS transistor NM70 and to the complementary global I/O line GIOB, and a second terminal of the seventh NMOS transistor NM72 may be connected to the first terminal of the third NMOS transistor NM68.

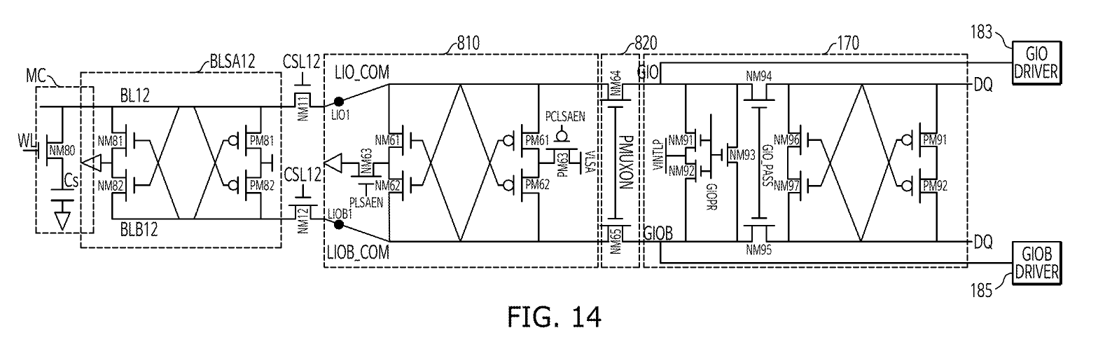

FIG. 14 is a circuit diagram for explaining a data flow while a read operation or a write operation for a memory cell is performed. Descriptions of configurations already given above with reference to FIG. 8 and the like are omitted below.

The memory cell MC for which a read operation or a write operation is performed may be a volatile memory cell. For example, the memory cell MC may be implemented by a transistor NM80 (e.g., an NMOS transistor) and a cell capacitor Cs. A first terminal of the transistor NM80 of the memory cell MC may be connected to the bit line BL12, a gate may be connected to a word line WL, and a second terminal may be connected to the cell capacitor Cs. In FIG. 14, for convenience of description, a read or write operation for the memory cell MC is illustrated and described using the bit line pair BL12, BLB12 and the bit line sense amplifier BLSA12 of FIG. 8, but the embodiments illustrated and described with reference to FIG. 14 are not limited thereto and may likewise be applied to a read operation or a write operation performed using any bit line pair and the bit line sense amplifier connected thereto inside the memory device.

The bit line sense amplifier BLSA12 may include a first NMOS transistor NM81, a second NMOS transistor NM82, a first PMOS transistor PM81, and a second PMOS transistor PM82. The bit line sense amplifier BLSA12 may detect (or sense) and amplify a signal from the memory cell MC.

A first terminal of the first NMOS transistor NM81 may be connected to the bit line BL12, a second terminal of the first NMOS transistor NM81 may be connected to the ground voltage line, and a gate of the first NMOS transistor NM81 may be connected to the complementary bit line BLB12.

A first terminal of the second NMOS transistor NM82 may be connected to the complementary bit line BLB12, a second terminal of the second NMOS transistor NM82 may be connected to the ground voltage line and to the second terminal of the first NMOS transistor NM81, and a gate of the second NMOS transistor NM82 may be connected to the bit line BL12.

A first terminal of the first PMOS transistor PM81 may be connected to the bit line BL12, a second terminal of the first PMOS transistor PM81 may be connected to an internal power voltage, and a gate of the first PMOS transistor PM81 may be connected to the complementary bit line BLB12.

A first terminal of the second PMOS transistor PM82 may be connected to the complementary bit line BLB12, a second terminal of the second PMOS transistor PM82 may be connected to the internal power voltage and to the second terminal of the first PMOS transistor PM81, and a gate of the second PMOS transistor PM82 may be connected to the bit line BL12.

In operation of these transistors, a voltage of the cell capacitor Cs may be transferred to the bit line BL12 through the transistor NM80, and the NMOS transistors NM81, NM82 and the PMOS transistors PM81, PM82 may amplify or regenerate a minute potential difference applied to the bit line pair BL12, BLB12, thereby supporting reading or writing of the stored data.

In an embodiment, the I/O sense amplifier 170 may include a plurality of NMOS transistors NM91~NM97 and a plurality of PMOS transistors PM91~PM92. The I/O sense amplifier 170 is not limited to the structure illustrated in FIG. 14 and may be implemented differently in various embodiments.

A first terminal of a first NMOS transistor NM91 may be connected to the global I/O line GIO and to one terminal (e.g., a second terminal) of the NMOS transistor NM64, a second terminal of the first NMOS transistor NM91 may be connected to a second terminal of a second NMOS transistor NM92 and to a precharge voltage line VINTLP, and a gate of the first NMOS transistor NM91 may be connected to a global precharge control signal line GIOPR.

A first terminal of the second NMOS transistor NM92 may be connected to the complementary global I/O line GIOB, a second terminal of the second NMOS transistor NM92 may be connected to the second terminal of the first NMOS transistor NM91 and to the precharge voltage line VINTLP, and a gate of the second NMOS transistor NM92 may be connected to the global precharge control signal line GIOPR.

A first terminal of a third NMOS transistor NM93 may be connected to the global I/O line GIO, a second terminal of the third NMOS transistor NM93 may be connected to the complementary global I/O line GIOB, and a gate of the third NMOS transistor NM93 may be connected to the global precharge control signal line GIOPR.

Gates of a fourth NMOS transistor NM94 and a fifth NMOS transistor NM95 may each be connected to a global I/O pass line GIO_PASS, and in response to turning on of the fourth NMOS transistor NM94 and the fifth NMOS transistor NM95 by the global I/O pass line GIO_PASS, data may be transferred to the DQ line through the global I/O line pair GIO, GIOB.

A sixth NMOS transistor NM96, a seventh NMOS transistor NM97, the first PMOS transistor PM91, and the second PMOS transistor PM92 may amplify signals of the global I/O line pair GIO, GIOB through a cross coupling structure and may transfer data to the DQ line (data path).

Using the circuit illustrated and described with reference to FIG. 14, a read operation or a write operation for the memory cell MC may be performed.

Referring to FIGS. 8 and 14 together, in response to initiation of a read operation for the memory cell MC connected to the first bit line pair BL12, BLB12, the bit line sense amplifier BLSA12 connected to the first bit line pair BL12, BLB12 may sense and amplify data stored in the memory cell MC and may transfer the sensed and amplified data to the common local sense amplifier 810 through the first local I/O line pair LIO1, LIOB1 and the common local I/O line pair LIO_COM, LIOB_COM. The common local sense amplifier 810 may amplify a voltage difference of the common local I/O line pair LIO_COM, LIOB_COM and may transfer data corresponding to the amplified voltage difference to the I/O sense amplifier 170 through the global I/O line pair GIO, GIOB. At this time, in response to initiation of the read operation for the memory cell MC, the plurality of switching elements TG11~TG14, TG21~TG24 may electrically connect the common local I/O line pair LIO_COM, LIOB_COM to the first local I/O line pair LIO1, LIOB1, and may electrically isolate the common local I/O line pair LIO_COM, LIOB_COM from the second local I/O line pair LIO2, LIOB2.

Referring to FIGS. 8 and 14 together, when a write operation for the memory cell MC is performed, the global I/O driver 183 (e.g., the GIO driver), 185 (e.g., the complementary global I/O (GIOB) driver) may receive write data for the memory cell connected to the first bit line pair BL12, BLB12 and may transfer the received write data to the common local sense amplifier 810 through the global I/O line pair GIO, GIOB. The common local sense amplifier 810 may transfer the received write data to the bit line sense amplifier BLSA12 through the common local I/O line pair LIO_COM, LIOB_COM and the first local I/O line pair LIO1, LIOB1. The bit line sense amplifier BLSA12 may deliver the write data to the memory cell MC through the first bit line pair BL12, BLB12 so that the write data is written into the memory cell MC connected to the first bit line pair BL12, BLB12. In response to initiation of the write operation for the memory cell MC, the plurality of switching elements TG11~TG14, TG21~TG24 may electrically connect the common local I/O line pair LIO_COM, LIOB_COM to the first local I/O line pair LIO1, LIOB1 and may electrically isolate the common local I/O line pair LIO_COM, LIOB_COM from the second local I/O line pair LIO2, LIOB2.

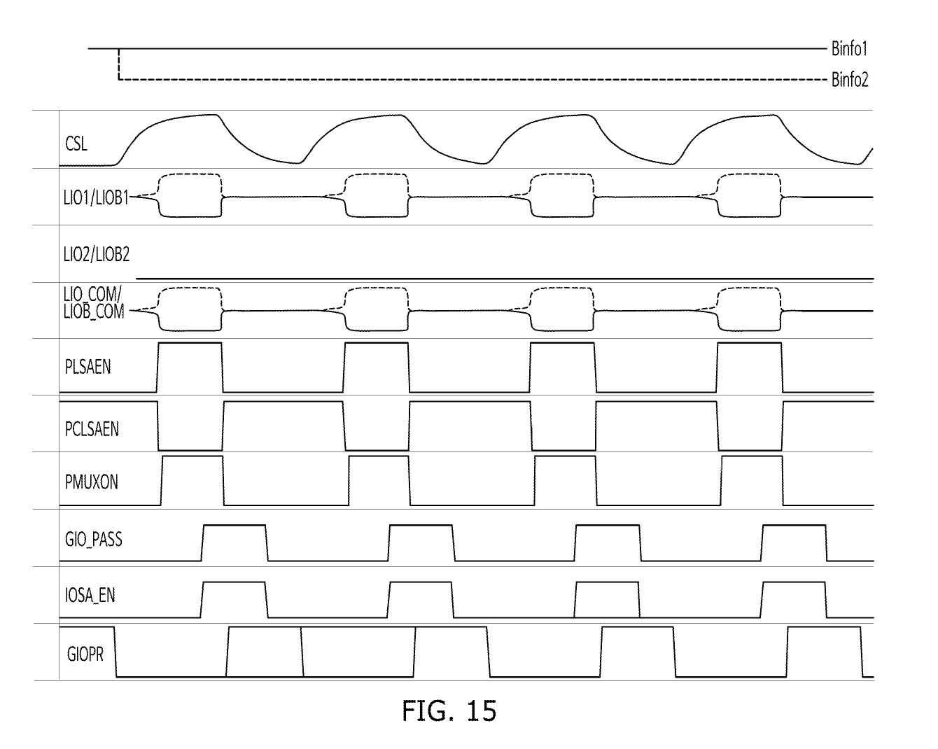

FIG. 15 is a waveform diagram exemplarily illustrating level changes and timing relationships of main control signals during a read operation in a circuit according to embodiments of the present disclosure. Levels of the main control signals illustrated in FIG. 15 may be controlled by the control logic circuit (e.g., item 150 of FIG. 1) of the memory device (e.g., item 100 of FIG. 1). Although FIG. 15 illustrates and describes performance of a read operation for some memory cells connected to bit lines, the same applies to performance of a read operation for any memory cell inside the memory device.

Referring to FIGS. 8, 11, and 15, in response to reception of an active (ACT) command, a specific row of the cell array may be activated, and a corresponding block select signal may be applied at a high level. For example, in FIG. 15, a first block select signal Binfo1 may be applied at a high level to the switching elements TG11, TG12, and a second block select signal Binfo2 may be applied at a low level to the switching elements TG21, TG22. That is, the block select signals Binfo1, Binfo2 may be set to indicate a sub cell array and/or a sub-row decoder for which a read operation will be performed in the current read operation cycle; a data path (e.g., a path connecting the common local I/O line pair of the relevant sub cell array to the global I/O line pair) for the selected sub cell array may be electrically connected, and data paths for other sub cell arrays may be electrically isolated.

In response to reception of the ACT command, a related bit line sense amplifier may be activated, and the bit line sense amplifier may sense and amplify data inside the memory cell through the bit line pair.

Referring to FIGS. 8, 14 and 15, when a column select signal CSL (e.g., CSL12 of FIG. 8) is then activated, the bit line pair BL12, BLB12 of the selected column and the local I/O line pair LIO1, LIOB1 may be connected, and activation signals PLSAEN and PCLSAEN of the local sense amplifier 810 may be applied to operate the local sense amplifier 810 so that a voltage difference appearing on the local I/O line pair LIO1, LIOB1 is amplified. Conversely, signals of the unconnected local I/O line pair LIO2, LIOB2 may be kept at a low level.

Signals amplified by the local sense amplifier 810 may be transferred to the global I/O line pair GIO, GIOB, as the connection control signal PMUXON of the switch circuit 820 is switched to a high level, through the common local I/O line pair LIO_COM, LIOB_COM. As illustrated in FIG. 15, during a read operation, after the global I/O pass line GIO_PASS is applied at a high level, an I/O sense amplifier activation signal IOSA_EN that activates the I/O sense amplifier 170 and the global precharge control signal line GIOPR are sequentially applied at a high level, whereby the I/O sense amplifier 170 may amplify signals of the global I/O line pair GIO, GIOB. Consequently, the above-described control signals cooperate during the read operation to generate a stable read data voltage on the global I/O line pair GIO, GIOB, and the read data can be output to the outside.

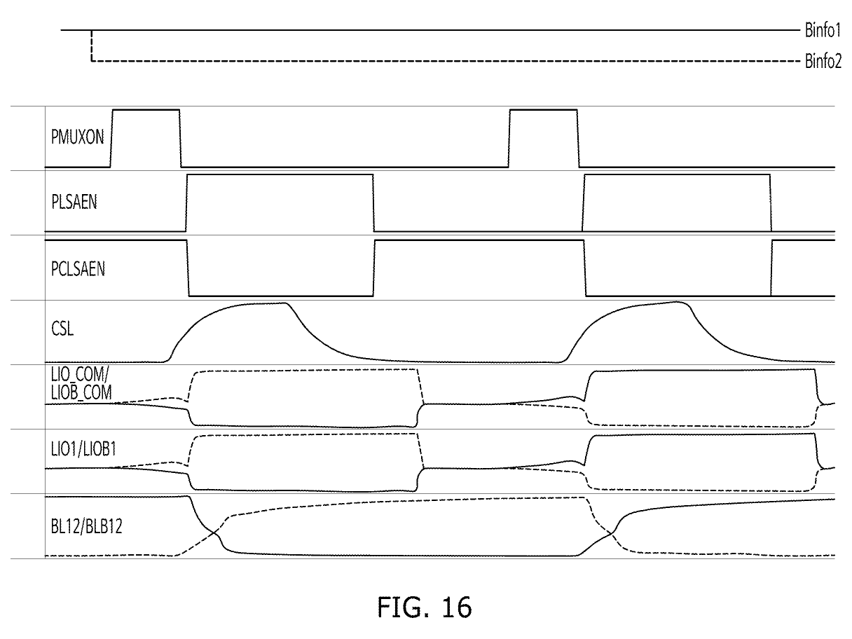

FIG. 16 is a waveform diagram exemplarily illustrating level changes and timing relationships of main control signals during a write operation in a circuit according to embodiments of the present disclosure. Levels of the main control signals illustrated in FIG. 16 may be controlled by the control logic circuit (e.g., item 150 of FIG. 1) of the memory device (e.g., item 100 of FIG. 1). Although FIG. 16 illustrates and describes performance of a write operation for some memory cells connected to bit lines, the same applies to performance of a write operation for any memory cell inside the memory device.

Referring to FIGS. 8, 11 and 16, in response to reception of an ACT command, a specific row of the cell array may be activated, and a corresponding block select signal may be applied at a high level. For example, in FIG. 16, a first block select signal Binfo1 may be applied at a high level to the switching elements TG11, TG12, and a second block select signal Binfo2 may be applied at a low level to the switching elements TG21, TG22. That is, the block select signals Binfo1, Binfo2 may be set to indicate a sub cell array and/or a sub-row decoder for which a write operation will be performed in the current write operation cycle; a data path (e.g., a path connecting the common local I/O line pair of the relevant sub cell array to the global I/O line pair) for the selected sub cell array may be electrically connected, and data paths for other sub cell arrays may be electrically isolated.

Referring to FIGS. 14 and 16, at the beginning of the cycle, a path of the selected sub cell array is set by the block select signals Binfo1, Binfo2, and then the global I/O pass line GIO_PASS is applied at a high level to activate the global I/O driver 183, 185 of the bank. As a result, voltage levels of the global I/O line pair GIO, GIOB may be split and changed according to the input data DQ.

The connection control signal PMUXON may be switched to a high level to connect the global I/O line pair GIO, GIOB to the common local I/O line pair LIO_COM, LIOB_COM.

Activation signals PLSAEN and PCLSAEN of the local sense amplifier 810 may then be applied at high level and low level, respectively, after the connection control signal PMUXON is switched to low level, whereby transistors to which the activation signals PLSAEN and PCLSAEN are applied to the gates may be activated.

When the column select signal CSL (e.g., CSL12 of FIG. 8) is applied at a high level, write data prepared on the local I/O line pair LIO1, LIOB1 through the common local I/O line pair LIO_COM, LIOB_COM may be written into the memory cell through the bit line pair BL12, BLB12 of the selected column. After writing is completed, the column select signal CSL may return to a low level to disconnect the bit line pair from the local I/O line pair LIO1, LIOB1. Through the series of signal operations as described above, during the write operation, the input data are eventually written into the memory cell, and unused paths or circuits are blocked by appropriate signals (e.g., Binfo2), thereby preventing operational interference.

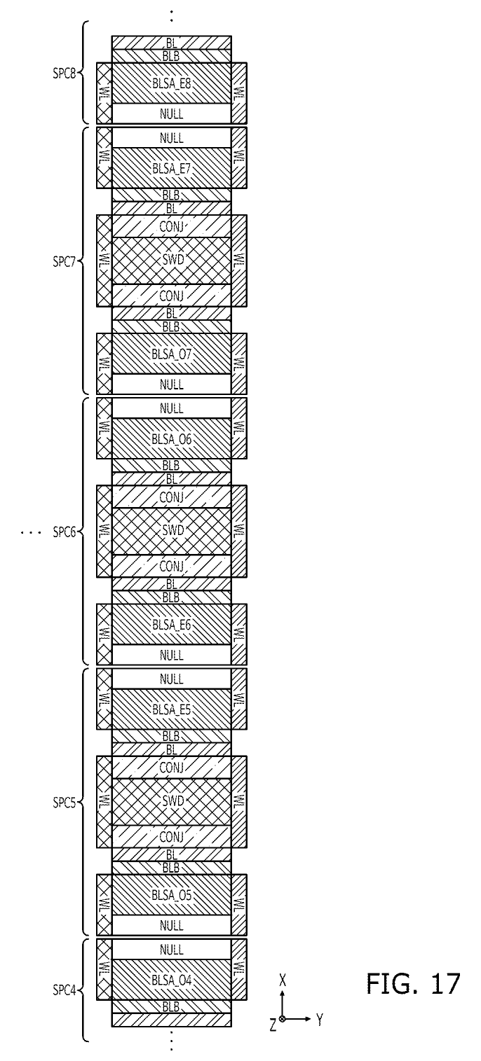

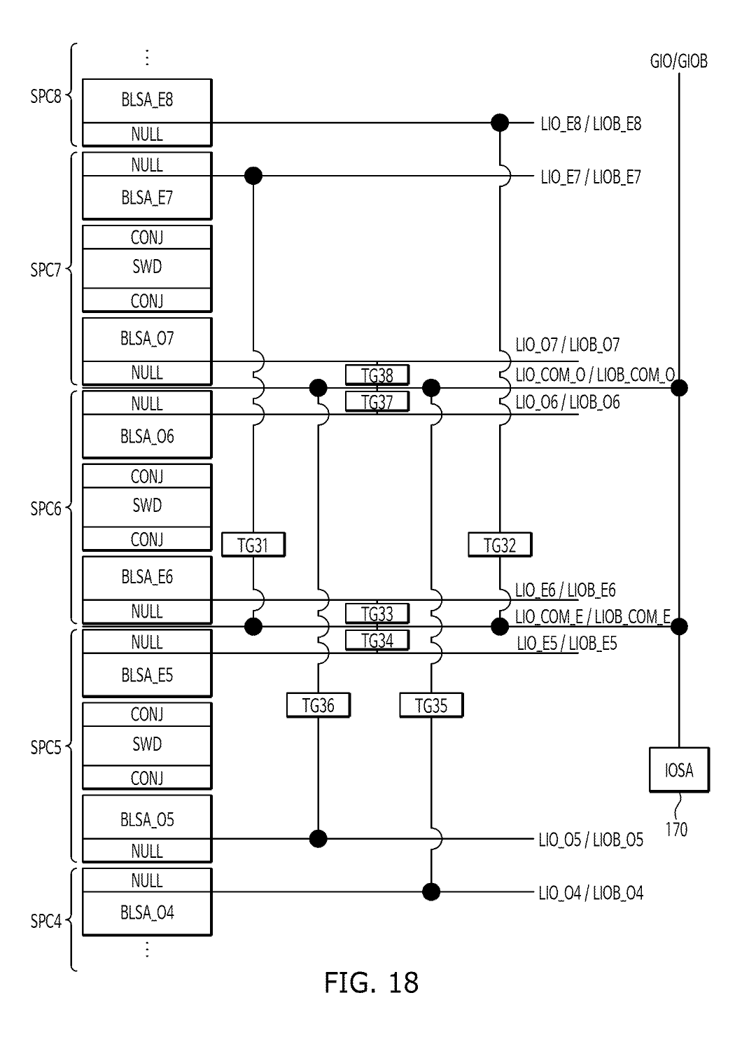

FIG. 17 is a diagram illustrating examples of sub-peripheral circuits SPC4~SPC8, which are part of the peripheral circuit CCC of FIGS. 4 and 18 is a diagram illustrating, in greater detail, circuit structures disposed in the sub-peripheral circuits SPC4~SPC8.

Referring to FIGS. 4 and 17, each of sub-peripheral circuit SPC4~SPC8 may be a circuit connected to any one of the sub cell arrays SCA of the cell array 110 of FIG. 4. Each of sub-peripheral circuit SPC4~SPC8 may be disposed above or below (e.g., in the +Z or –Z direction) the respective sub cell array connected to the sub-peripheral circuit SPC4~SPC8.

Each of sub-peripheral circuit SPC4~SPC8 may include a respective one of bit line sense amplifier regions BLSA_O4~BLSA_O7, a respective one of bit line sense amplifier regions BLSA_E5~BLSA_E8, sub-word line driver regions SWD, conjunction regions CONJ, and null regions NULL.

Each of bit line sense amplifier region BLSA_O4~BLSA_O7 and BLSA_E5~BLSA_E8 may be connected to the sub cell array connected to the respective sub-peripheral circuit SPC4~SPC8.

Each of bit line sense amplifier region BLSA_O4~BLSA_O7 and BLSA_E5~BLSA_E8 may include a plurality of bit line sense amplifiers. Each of bit line sense amplifier region BLSA_O4~BLSA_O7 and BLSA_E5~BLSA_E8 may be connected to the sub cell array through bit line pairs BL and BLB disposed adjacent to the respective bit line sense amplifier region.

Each of sub-peripheral circuit SPC4~SPC8 may include two bit line sense amplifier regions. For example, each of sub-peripheral circuit SPC4~SPC8 may include a respective one of bit line sense amplifier regions BLSA_O4~BLSA_O7 that include bit line sense amplifiers respectively connected to odd numbered bit line pairs and a respective one of bit line sense amplifier regions BLSA_E5~BLSA_E8 that include bit line sense amplifiers respectively connected to even numbered bit line pairs. Each of bit line sense amplifier regions BLSA_O4~BLSA_O7 or each of bit line sense amplifier regions BLSA_E5~BLSA_E8 may include a plurality of bit line sense amplifiers respectively connected to even numbered (or odd numbered) bit lines. Each of the plurality of bit line sense amplifiers may be connected to a sub cell array through a respective bit line pair.

In an example, between adjacent sub-peripheral circuits among the sub-peripheral circuits SPC4~SPC8, bit line sense amplifier regions that include bit line sense amplifiers respectively connected to even numbered bit line pairs may be disposed adjacent to each other, or bit line sense amplifier regions that include bit line sense amplifiers respectively connected to odd numbered bit line pairs may be disposed adjacent to each other. For example, the bit line sense amplifier region BLSA_O4 of the fourth sub-peripheral circuit SPC4, which includes bit line sense amplifiers respectively connected to odd numbered bit line pairs, and the bit line sense amplifier region BLSA_O5 of the fifth sub-peripheral circuit SPC5, which includes bit line sense amplifiers respectively connected to odd numbered bit line pairs, may be disposed adjacent to each other. Contrary to what is illustrated in FIG. 17, in another embodiment, an un-illustrated bit line sense amplifier region connected to even numbered bit line pairs in the fourth sub-peripheral circuit SPC4 and the bit line sense amplifier region BLSA_E5 connected to even numbered bit line pairs in the fifth sub-peripheral circuit SPC5 may be disposed adjacent to each other.

For each of the sub-word line driver regions (SWD), conjunction regions (CONJ), and null regions (NULL) of the sub-peripheral circuits (SPC4~SPC8), the embodiments described above with reference to FIG. 7 for the sub-word line driver regions (SWD), conjunction regions (CONJ), and null regions (NULL) of the sub-peripheral circuits (SPC1~SPC2) can be equally applied, as shown in FIG. 7.

Referring to FIG. 18, in the null regions NULL, local I/O line pairs LIO_O4~LIO_O7, LIOB_O4~LIOB_O7, LIO_E5~LIO_E8, LIOB_E5~LIOB_E8, common local I/O line pairs LIO_COM_E, LIOB_COM_E, LIO_COM_O, LIOB_COM_O, a plurality of switching elements TG31~TG38, a common local sense amplifier, and a switch circuit may be disposed. However, the configuration is not limited thereto, and some components or a part of a specific component may be disposed outside the null regions NULL.

The local I/O line pair LIO_O4, LIOB_O4 may be electrically connected to a bit line sense amplifier in the bit line sense amplifier region BLSA_O4 of the fourth sub-peripheral circuit SPC4. For example, the local I/O line pair LIO_O4, LIOB_O4 may be electrically connected to a bit line pair connected to the bit line sense amplifier in the bit line sense amplifier region BLSA_O4.

The local I/O line pair LIO_O5, LIOB_O5 may be electrically connected to a bit line sense amplifier in the bit line sense amplifier region BLSA_O5 of the fifth sub-peripheral circuit SPC5. For example, the local I/O line pair LIO_O5, LIOB_O5 may be electrically connected to a bit line pair connected to the bit line sense amplifier in the bit line sense amplifier region BLSA_O5.

The local I/O line pair LIO_E5, LIOB_E5 may be electrically connected to a bit line sense amplifier in the bit line sense amplifier region BLSA_E5 of the fifth sub-peripheral circuit SPC5. For example, the local I/O line pair LIO_E5, LIOB_E5 may be electrically connected to a bit line pair connected to the bit line sense amplifier in the bit line sense amplifier region BLSA_E5.

The local I/O line pair LIO_E6, LIOB_E6 may be electrically connected to a bit line sense amplifier in the bit line sense amplifier region BLSA_E6 of the sixth sub-peripheral circuit SPC6. For example, the local I/O line pair LIO_E6, LIOB_E6 may be electrically connected to a bit line pair connected to the bit line sense amplifier in the bit line sense amplifier region BLSA_E6.

The local I/O line pair LIO_O6, LIOB_O6 may be electrically connected to a bit line sense amplifier in the bit line sense amplifier region BLSA_O6 of the sixth sub-peripheral circuit SPC6. For example, the local I/O line pair LIO_O6, LIOB_O6 may be electrically connected to a bit line pair connected to the bit line sense amplifier in the bit line sense amplifier region BLSA_O6.

The local I/O line pair LIO_O7, LIOB_O7 may be electrically connected to a bit line sense amplifier in the bit line sense amplifier region BLSA_O7 of the seventh sub-peripheral circuit SPC7. For example, the local I/O line pair LIO_O7, LIOB_O7 may be electrically connected to a bit line pair connected to the bit line sense amplifier in the bit line sense amplifier region BLSA_O7.

The local I/O line pair LIO_E7, LIOB_E7 may be electrically connected to a bit line sense amplifier in the bit line sense amplifier region BLSA_E7 of the seventh sub-peripheral circuit SPC7. For example, the local I/O line pair LIO_E7, LIOB_E7 may be electrically connected to a bit line pair connected to the bit line sense amplifier in the bit line sense amplifier region BLSA_E7.

The local I/O line pair LIO_E8, LIOB_E8 may be electrically connected to a bit line sense amplifier in the bit line sense amplifier region BLSA_E8 of the eighth sub-peripheral circuit SPC8. For example, the local I/O line pair LIO_E8, LIOB_E8 may be electrically connected to a bit line pair connected to the bit line sense amplifier in the bit line sense amplifier region BLSA_E8.

The above-described local I/O line pairs LIO_O4~LIO_O7, LIOB_O4~LIOB_O7, LIO_E5~LIO_E8, and LIOB_E5~LIOB_E8 may be connected to bit line sense amplifiers in the same manner as in the embodiment described above with reference to FIG. 8. For example, between each of the local I/O line pairs LIO_O4~LIO_O7, LIOB_O4~LIOB_O7, LIO_E5~LIO_E8, LIOB_E5~LIOB_E8 and a respective bit line sense amplifier, a column select transistor whose gate receives a column select signal may be connected. In response to turning on of a column select transistor corresponding to a bit line sense amplifier, the local I/O line pair and the bit line sense amplifier may be electrically connected.

The local I/O line pairs LIO_O4~LIO_O7, LIOB_O4~LIOB_O7 and the local I/O line pairs LIO_E5~LIO_E8, LIOB_E5~LIOB_E8 may include a local I/O line LIO_O4~LIO_O7, LIO_E5~LIO_E8 and a complementary local I/O line LIOB_O4~LIOB_O7, LIOB_E5~LIOB_E8. Each of local I/O line LIO_O4~LIO_O7, LIO_E5~LIO_E8 may be connected to a bit line, and each of complementary local I/O line LIOB_O4~LIOB_O7, LIOB_E5~LIOB_E8 may be connected to a complementary bit line.

A first common local I/O line pair LIO_COM_E, LIOB_COM_E may be connected to the local I/O line pairs LIO_E5~LIO_E8, LIOB_E5~LIOB_E8. The first common local I/O line pair LIO_COM_E, LIOB_COM_E may include a first common local I/O line LIO_COM_E and a first complementary common local I/O line LIOB_COM_E. The first common local I/O line LIO_COM_E may be connected to the local I/O lines LIO_E5~LIO_E8, and the first complementary common local I/O line LIOB_COM_E may be connected to the complementary local I/O lines LIOB_E5~LIOB_E8. The bit line sense amplifiers connected to the local I/O line pairs LIO_E5~LIO_E8, LIOB_E5~LIOB_E8 may be connected to bit line pairs that are all even numbered bit line pairs (or all odd numbered bit line pairs).

The plurality of switching elements TG31~TG34 may electrically connect the first common local I/O line pair LIO_COM_E, LIOB_COM_E to any one of the local I/O line pairs LIO_E5~LIO_E8, LIOB_E5~LIOB_E8 and may electrically isolate the first common local I/O line pair LIO_COM_E, LIOB_COM_E from the remainder of the local I/O line pairs LIO_E5~LIO_E8, LIOB_E5~LIOB_E8.

For example, the plurality of switching elements TG31~TG34 may include a plurality of first switching elements TG31 connected to the local I/O line pair LIO_E7, LIOB_E7, a plurality of second switching elements TG32 connected to the local I/O line pair LIO_E8, LIOB_E8, a plurality of third switching elements TG33 connected to the local I/O line pair LIO_E6, LIOB_E6, and a plurality of fourth switching elements TG34 connected to the local I/O line pair LIO_E5, LIOB_E5.

The plurality of first switching elements TG31 may be turned on in response to initiation of a read operation or a write operation for the sub cell array connected to the seventh sub-peripheral circuit SPC7 and may be turned off in response to initiation of a read operation or a write operation for the sub cell arrays connected to the fifth, sixth, and eighth sub-peripheral circuits SPC5, SPC6, SPC8.

The plurality of second switching elements TG32 may be turned on in response to initiation of a read operation or a write operation for the sub cell array connected to the eighth sub-peripheral circuit SPC8 and may be turned off in response to initiation of a read operation or a write operation for the sub cell arrays connected to the fifth, sixth, and seventh sub-peripheral circuits SPC5, SPC6, SPC7.

The plurality of third switching elements TG33 may be turned on in response to initiation of a read operation or a write operation for the sub cell array connected to the sixth sub-peripheral circuit SPC6 and may be turned off in response to initiation of a read operation or a write operation for the sub cell arrays connected to the fifth, seventh, and eighth sub-peripheral circuits SPC5, SPC7, SPC8.

The plurality of fourth switching elements TG34 may be turned on in response to initiation of a read operation or a write operation for the sub cell array connected to the fifth sub-peripheral circuit SPC5 and may be turned off in response to initiation of a read operation or a write operation for the sub cell arrays connected to the sixth, seventh, and eighth sub-peripheral circuits SPC6, SPC7, SPC8.

A second common local I/O line pair LIO_COM_O, LIOB_COM_O may be connected to the local I/O line pairs LIO_O4~LIO_O7, LIOB_O4~LIOB_O7. The second common local I/O line pair LIO_COM_O, LIOB_COM_O may include a second common local I/O line LIO_COM_O and a second complementary common local I/O line LIOB_COM_O. The second common local I/O line LIO_COM_O may be connected to the local I/O lines LIO_O4~LIO_O7, and the second complementary common local I/O line LIOB_COM_O may be connected to the complementary local I/O lines LIOB_O4~LIOB_O7. The bit line sense amplifiers connected to the local I/O line pairs LIO_O4~LIO_O7, LIOB_O4~LIOB_O7 may be connected to bit line pairs that are all odd numbered bit line pairs (or all even numbered bit line pairs).

The plurality of switching elements TG35~TG38 may electrically connect the second common local I/O line pair LIO_COM_O, LIOB_COM_O to any one of the local I/O line pairs LIO_O4~LIO_O7, LIOB_O4~LIOB_O7 and may electrically isolate the second common local I/O line pair LIO_COM_O, LIOB_COM_O from the remainder of the local I/O line pairs LIO_O4~LIO_O7, LIOB_O4~LIOB_O7.

For example, the plurality of switching elements TG35~TG38 may include a plurality of fifth switching elements TG35 connected to the local I/O line pair LIO_O4, LIOB_O4, a plurality of sixth switching elements TG36 connected to the local I/O line pair LIO_O5, LIOB_O5, a plurality of seventh switching elements TG37 connected to the local I/O line pair LIO_O6, LIOB_O6, and a plurality of eighth switching elements TG38 connected to the local I/O line pair LIO_O7, LIOB_O7.

The plurality of fifth switching elements TG35 may be turned on in response to initiation of a read operation or a write operation for the sub cell array connected to the fourth sub-peripheral circuit SPC4 and may be turned off in response to initiation of a read operation or a write operation for the sub cell arrays connected to the fifth, sixth, and seventh sub-peripheral circuits SPC5, SPC6, SPC7.

The plurality of sixth switching elements TG36 may be turned on in response to initiation of a read operation or a write operation for the sub cell array connected to the fifth sub-peripheral circuit SPC5 and may be turned off in response to initiation of a read operation or a write operation for the sub cell arrays connected to the fourth, sixth, and seventh sub-peripheral circuits SPC4, SPC6, SPC7.

The plurality of seventh switching elements TG37 may be turned on in response to initiation of a read operation or a write operation for the sub cell array connected to the sixth sub-peripheral circuit SPC6 and may be turned off in response to initiation of a read operation or a write operation for the sub cell arrays connected to the fourth, fifth, and seventh sub-peripheral circuits SPC4, SPC5, SPC7.

The plurality of eighth switching elements TG38 may be turned on in response to initiation of a read operation or a write operation for the sub cell array connected to the seventh sub-peripheral circuit SPC7 and may be turned off in response to initiation of a read operation or a write operation for the sub cell arrays connected to the fourth, fifth, and sixth sub-peripheral circuits SPC4, SPC5, SPC6.

The plurality of switching elements TG31~TG38 may include transmission gate circuits. The plurality of switching elements TG31~TG38 may be implemented identically to the embodiment described above with reference to FIG. 11.

Each of the first common local I/O line pair LIO_COM_E, LIOB_COM_E and the second common local I/O line pair LIO_COM_O, LIOB_COM_O may be connected to a common local sense amplifier and a switch circuit. The common local sense amplifier and the switch circuit connected respectively to the first common local I/O line pair LIO_COM_E, LIOB_COM_E and the second common local I/O line pair LIO_COM_O, LIOB_COM_O may be implemented identically to the common local sense amplifier embodiment and the switch circuit embodiment described above with reference to FIGS. 8, 10 and 12, or alternatively may be implemented identically to the circuit structure described above with reference to FIG. 13.

For example, the common local sense amplifier connected respectively to each of the first common local I/O line pair LIO_COM_E, LIOB_COM_E and the second common local I/O line pair LIO_COM_O, LIOB_COM_O may amplify a voltage level transferred from each of the first and second common local I/O line pairs LIO_COM_E, LIOB_COM_E and LIO_COM_O, LIOB_COM_O and may transfer the amplified level to the I/O sense amplifier 170 through the global I/O line pair GIO, GIOB. The switch circuit connected respectively to each of the first and second common local I/O line pairs may electrically connect the common local sense amplifier and the global I/O line pair GIO, GIOB in response to initiation of a read operation or a write operation for a sub cell array.

The global I/O line pair GIO, GIOB may include a global I/O line GIO and a complementary global I/O line GIOB. The global I/O line GIO may be connected to the common local I/O lines LIO_COM_E and LIO_COM_O, and the complementary global I/O line GIOB may be connected to the complementary common local I/O lines LIOB_COM_E and LIOB_COM_O.

The I/O sense amplifier 170 may be electrically connected to the global I/O line pair GIO, GIOB.

Although an embodiment in which four local I/O lines are connected to a common local I/O line is illustrated and described with reference to FIGS. 17 and 18, the present disclosure is not limited thereto. For example, (2ⁿ) local I/O lines (where n is a natural number) may be connected to a common local I/O line.

Through the circuit structure illustrated and described with reference to FIGS. 17 and 18, parasitic resistance and/or parasitic capacitance associated with the global I/O line pair GIO, GIOB can be further effectively reduced, a bottleneck in data transfer using the global I/O line pair GIO, GIOB can be further reduced, and data transfer speed can be further improved by reducing loading of the global I/O line pair GIO, GIOB. Because transistor sizes of the common local sense amplifier and/or the switch circuit can be enlarged further within the same device layout area, data transfer speed can be further improved.

The circuit structure illustrated and described with reference to FIGS. 17 and 18 may be arranged in a repetitive pattern on the peripheral circuit. For example, the circuit structure illustrated and described with reference to FIGS. 17 and 18 may be repeatedly arranged in the X and Y directions in the peripheral circuit CCC of FIG. 4.

The present disclosure is not limited by the above-described embodiments and the attached drawings, and various substitutions, modifications, and changes may be made by those skilled in the art without departing from the technical spirit of the present disclosure, and those substitutions, modifications, and changes are also within the scope of the present disclosure.

What is claimed is:

1. A memory device, comprising:
a cell array including a first sub cell array and a second sub cell array;
a first bit line sense amplifier connected to the first sub cell array;
a second bit line sense amplifier connected to the second sub cell array;
a first local input/output (I/O) line pair electrically connected to a first bit line pair connected to the first bit line sense amplifier;
a second local I/O line pair electrically connected to a second bit line pair connected to the second bit line sense amplifier;
a common local I/O line pair connected to the first local I/O line pair and the second local I/O line pair;
a common local sense amplifier configured to amplify a voltage level transferred from the common local I/O line pair;
a global I/O line pair connected to the common local sense amplifier; and
an I/O sense amplifier electrically connected to the global I/O line pair.

2. The memory device as claimed in claim 1, wherein the common local sense amplifier is disposed between a first set of bit line sense amplifiers, which includes the first bit line sense amplifier and is connected to the first sub cell array, and a second set of bit line sense amplifiers, which includes the second bit line sense amplifier and is connected to the second sub cell array.

3. The memory device as claimed in claim 1, wherein the common local I/O line pair comprises a common local I/O line and a complementary common local I/O line, and the common local sense amplifier comprises:
a first NMOS transistor having a first terminal connected to the common local I/O line and a gate connected to the complementary common local I/O line;
a second NMOS transistor having a first terminal connected to the complementary common local I/O line, a second terminal connected to a second terminal of the first NMOS transistor, and a gate connected to the common local I/O line;
a third NMOS transistor configured to be turned on in response to a first activation signal applied to a gate of the third NMOS transistor, the third NMOS transistor having a first terminal connected to a ground voltage line and a second terminal connected to the second terminals of the first and second NMOS transistors;
a first PMOS transistor having a first terminal connected to the common local I/O line and a gate connected to the complementary common local I/O line;
a second PMOS transistor having a first terminal connected to the complementary common local I/O line, a second terminal connected to a second terminal of the first PMOS transistor, and a gate connected to the common local I/O line; and
a third PMOS transistor configured to be turned on in response to a second activation signal applied to a gate of the third PMOS transistor, the third PMOS transistor having a first terminal connected to an internal power line and a second terminal connected to the second terminals of the first and second PMOS transistors.

4. The memory device as claimed in claim 1, further comprising a switch circuit configured to electrically connect the common local sense amplifier and the global I/O line pair in response to initiation of a read operation or a write operation for either the first sub cell array or the second sub cell array.

5. The memory device as claimed in claim 4, wherein the common local I/O line pair comprises a common local I/O line and a complementary common local I/O line,
the global I/O line pair comprises a global I/O line and a complementary global I/O line, and
the switch circuit comprises:
a first transistor configured to be turned on in response to initiation of the read operation or the write operation, the first transistor having a first terminal connected to the common local I/O line, and a second terminal connected to the global I/O line; and
a second transistor configured to be turned on in response to initiation of the read operation or the write operation, the second transistor having a first terminal connected to the complementary common local I/O line, and a second terminal connected to the complementary global I/O line.

6. The memory device as claimed in claim 1, further comprising a plurality of switching elements configured to electrically connect the common local I/O line pair to one of the first local I/O line pair or the second local I/O line pair and to electrically isolate the common local I/O line pair from the other of the first local I/O line pair or the second local I/O line pair.

7. The memory device as claimed in claim 6, wherein the plurality of switching elements comprise a plurality of first switching elements connected to the first local I/O line pair and a plurality of second switching elements connected to the second local I/O line pair,
the plurality of first switching elements configured to turn on in response to initiation of a read operation or a write operation for the first sub cell array and to turn off in response to initiation of a read operation or a write operation for the second sub cell array, and
the plurality of second switching elements configured to turn on in response to initiation of a read operation or a write operation for the second sub cell array and to turn off in response to initiation of a read operation or a write operation for the first sub cell array.

8. The memory device as claimed in claim 1, wherein the first bit line sense amplifier is configured to, in response to initiation of a read operation for a memory cell connected to the first bit line pair, sense and amplify data stored in the memory cell and transmit the sensed and amplified data to the common local sense amplifier through the first local I/O line pair and the common local I/O line pair, and
the common local sense amplifier is configured to amplify a voltage difference of the common local I/O line pair and transmit data corresponding to the amplified voltage difference to the I/O sense amplifier through the global I/O line pair.

9. The memory device as claimed in claim 8, further comprising a plurality of switching elements configured to, in response to initiation of the read operation for the memory cell connected to the first bit line pair, electrically connect the common local I/O line pair to the first local I/O line pair and electrically isolate the common local I/O line pair from the second local I/O line pair.

10. The memory device as claimed in claim 1, further comprising a global I/O driver, wherein the global I/O driver is configured to receive write data for a memory cell connected to the first bit line pair and transmit the received write data to the common local sense amplifier through the global I/O line pair,
the common local sense amplifier is configured to transmit the received write data to the first bit line sense amplifier through the common local I/O line pair and the first local I/O line pair, and
the first bit line sense amplifier is configured to deliver the write data to the memory cell through the first bit line pair so that the write data is written into the memory cell connected to the first bit line pair.

11. The memory device as claimed in claim 10, further comprising a plurality of switching elements configured to, in response to initiation of a write operation for the memory cell connected to the first bit line pair, electrically connect the common local I/O line pair to the first local I/O line pair and electrically isolate the common local I/O line pair from the second local I/O line pair.

12. The memory device as claimed in claim 1, wherein the first bit line pair and the second bit line pair are both even numbered bit line pairs or are both odd numbered bit line pairs.

13. The memory device as claimed in claim 1, wherein the cell array further comprises a third sub cell array and a fourth sub cell array, the memory device further comprising:
a third bit line sense amplifier connected to the third sub cell array;
a fourth bit line sense amplifier connected to the fourth sub cell array;
a third local I/O line pair electrically connected to a third bit line pair connected to the third bit line sense amplifier;
a fourth local I/O line pair electrically connected to a fourth bit line pair connected to the fourth bit line sense amplifier; and
a plurality of switching elements,
wherein the common local I/O line pair is further connected to the third local I/O line pair and the fourth local I/O line pair, and the plurality of switching elements are further configured to electrically connect the common local I/O line pair to one of the first to fourth local I/O line pairs and electrically isolate the common local I/O line pair from the remainder of the first to fourth local I/O line pairs.

14. The memory device as claimed in claim 13, wherein the plurality of switching elements comprise:
a plurality of first switching elements connected to the first local I/O line pair,
a plurality of second switching elements connected to the second local I/O line pair,
a plurality of third switching elements connected to the third local I/O line pair, and
a plurality of fourth switching elements connected to the fourth local I/O line pair, and
the plurality of first switching elements is configured to turn on in response to initiation of a read operation or a write operation for the first sub cell array and to turn off in response to initiation of a read operation or a write operation for the second, third, or fourth sub cell array,
the plurality of second switching elements is configured to turn on in response to initiation of a read operation or a write operation for the second sub cell array and to turn off in response to initiation of a read operation or a write operation for the first, third, or fourth sub cell array,
the plurality of third switching elements is configured to turn on in response to initiation of a read operation or a write operation for the third sub cell array and to turn off in response to initiation of a read operation or a write operation for the first, second, or fourth sub cell array, and
the plurality of fourth switching elements is configured to turn on in response to initiation of a read operation or a write operation for the fourth sub cell array and to turn off in response to initiation of a read operation or a write operation for the first, second, or third sub cell array.

15. The memory device as claimed in claim 13, wherein the first bit line pair, the second bit line pair, the third bit line pair, and the fourth bit line pair are all even numbered bit line pairs or are all odd numbered bit line pairs.

16. A memory device, comprising:
a cell array including a first sub cell array and a second sub cell array;
a first bit line sense amplifier connected to the first sub cell array;
a second bit line sense amplifier connected to the second sub cell array;
a first local I/O line pair electrically connected to a first bit line pair connected to the first bit line sense amplifier;
a second local I/O line pair electrically connected to a second bit line pair connected to the second bit line sense amplifier;
a common local I/O line pair, connected to the first local I/O line pair and the second local I/O line pair, the common local I/O line pair including a common local I/O line and a complementary common local I/O line;
a plurality of transmission gate circuits configured to electrically connect the common local I/O line pair to one of the first local I/O line pair or the second local I/O line pair and to electrically isolate the common local I/O line pair from the other of the first local I/O line pair or the second local I/O line pair;
a common local sense amplifier, disposed between a first set of bit line sense amplifiers that includes the first bit line sense amplifier and is connected to the first sub cell array and a second set of bit line sense amplifiers that includes the second bit line sense amplifier and is connected to the second sub cell array, and configured to amplify a voltage level transferred from the common local I/O line pair;
a global I/O line pair connected to the common local sense amplifier; and
an I/O sense amplifier electrically connected to the global I/O line pair,
wherein the common local sense amplifier comprises:
a first NMOS transistor having a first terminal connected to the common local I/O line and a gate connected to the complementary common local I/O line;
a second NMOS transistor having a first terminal connected to the complementary common local I/O line, a second terminal connected to a second terminal of the first NMOS transistor, and a gate connected to the common local I/O line;
a third NMOS transistor configured to be turned on in response to a first activation signal applied to a gate of the third NMOS transistor, the third NMOS transistor having a first terminal connected to a ground voltage line and a second terminal connected to the second terminals of the first and second NMOS transistors;
a first PMOS transistor having a first terminal connected to the common local I/O line and a gate connected to the complementary common local I/O line;
a second PMOS transistor having a first terminal connected to the complementary common local I/O line, a second terminal connected to a second terminal of the first PMOS transistor, and a gate connected to the common local I/O line; and
a third PMOS transistor configured to be turned on in response to a second activation signal applied to a gate of the third PMOS transistor, the third PMOS transistor having a first terminal connected to an internal power line and a second terminal connected to the second terminals of the first and second PMOS transistors.

17. A peripheral circuit, comprising:
a first bit line sense amplifier connected to a first sub cell array of a cell array;
a second bit line sense amplifier connected to a second sub cell array of the cell array;
a first local I/O line pair electrically connected to a first bit line pair connected to the first bit line sense amplifier;
a second local I/O line pair electrically connected to a second bit line pair connected to the second bit line sense amplifier;
a first common local I/O line pair connected to the first local I/O line pair and the second local I/O line pair;
a first common local sense amplifier configured to amplify a voltage level transferred from the first common local I/O line pair;
a global I/O line pair connected to the first common local sense amplifier; and
an I/O sense amplifier electrically connected to the global I/O line pair,
wherein the peripheral circuit is disposed below or above the cell array.

18. The peripheral circuit as claimed in claim 17, further comprising:
a third bit line sense amplifier connected to the second sub cell array;
a fourth bit line sense amplifier connected to a third sub cell array of the cell array;
a third local I/O line pair electrically connected to a third bit line pair connected to the third bit line sense amplifier;
a fourth local I/O line pair electrically connected to a fourth bit line pair connected to the fourth bit line sense amplifier;
a second common local I/O line pair connected to the third local I/O line pair and the fourth local I/O line pair; and
a second common local sense amplifier configured to amplify a voltage level transferred from the second common local I/O line pair,
wherein the global I/O line pair is further connected to the second common local sense amplifier.

19. The peripheral circuit as claimed in claim 18, wherein the first bit line pair and the second bit line pair are both even numbered bit line pairs, and the third bit line pair and the fourth bit line pair are both odd numbered bit line pairs.

20. The peripheral circuit as claimed in claim 18, further comprising:
a plurality of first switching elements configured to electrically connect the first common local I/O line pair to one of the first local I/O line pair or the second local I/O line pair and to electrically isolate the first common local I/O line pair from the other of the first local I/O line pair or the second local I/O line pair, and
a plurality of second switching elements configured to electrically connect the second common local I/O line pair to one of the third local I/O line pair or the fourth local I/O line pair and to electrically isolate the second common local I/O line pair from the other of the third local I/O line pair or the fourth local I/O line pair.
